(19) United States
(12) Patent Application Publication
(10) Pub. No.: US 2026/0171163 A1
(43) Pub. Date: Jun. 18, 2026

(54) MEMORY DEVICE INCLUDING PAGE BUFFER CIRCUIT

(71) Applicant: SK hynix Inc., Icheon-si (KR)

(72) Inventors: Sung Lae OH, Icheon-si (KR); Sang Hyun SUNG, Icheon-si (KR)

(21) Appl. No.: 19/189,174

(22) Filed: Apr. 24, 2025

(30) Foreign Application Priority Data
Dec. 18, 2024 (KR) 10-2024-0190473

(51) Int. Cl. G11C 16/26; G11C 5/06; G11C 16/04; G11C 16/08; G11C 16/10

(52) U.S. Cl. CPC G11C 16/26; G11C 5/063; G11C 16/0483; G11C 16/08; G11C 16/10

(57) ABSTRACT

A memory device includes a plurality of input/output pins; and a page buffer circuit including a plurality of page buffers that are disposed in an M (M is an integer of 4 or greater) number of stages in a first direction and each of which is connected to one of the plurality of input/output pins, wherein the plurality of input/output pins include input/output pins of a first group and input/output pins of a second group, and wherein page buffers connected to the input/output pins of the first group and page buffers connected to the input/output pins of the second group are separated and are disposed in a first page buffer region and a second page buffer region, respectively.

### CROSS-REFERENCE TO RELATED APPLICATION

The present application claims priority under 35 U.S.C. § 119(a) to Korean Patent Application No. 10-2024-0190473 filed in the Korean Intellectual Property Office on Dec. 18, 2024, which is incorporated herein by reference in its entirety.

### BACKGROUND

### 1. Technical Field

Embodiments of the present disclosure relate to a memory device including a page buffer circuit.

### 2. Related Art

A NAND flash memory device is widely used as a data storage device. The NAND flash memory device may perform operations necessary to read and output data stored in memory cells by using a page buffer circuit.

### SUMMARY

In an embodiment, a memory device may include: a plurality of input/output pins; and a page buffer circuit including a plurality of page buffers that are disposed in a plurality of stages in a first direction, each of the plurality of page buffers is connected to one of the plurality of input/output pins, wherein the plurality of input/output pins include input/output pins of a first group and input/output pins of a second group, and wherein page buffers connected to the input/output pins of the first group and page buffers connected to the input/output pins of the second group are divided into a first page buffer region corresponding to the first group and a second page buffer region corresponding to the second group, respectively.

In an embodiment, a memory device may include: a plurality of input/output pins; and a page buffer circuit including a plurality of page buffers that are disposed in a plurality of stages in a first direction, each of the plurality of page buffers is connected to one of the plurality of input/output pins, wherein the plurality of input/output pins include input/output pins of a first group, input/output pins of a second group, input/output pins of a third group and input/output pins of a fourth group, and wherein page buffers connected to the input/output pins of the first group, page buffers connected to the input/output pins of the second group, page buffers connected to the input/output pins of the third group and page buffers connected to the input/output pins of the fourth group are separated and are arranged into a first page buffer region, a second page buffer region, a third page buffer region and a fourth page buffer region, respectively.

### BRIEF DESCRIPTION OF THE DRAWINGS

The present disclosure will be more fully understood from the detailed description and accompanying drawings provided below, which are provided for illustration only and are not intended to limit the present disclosure.

FIG. 1 is a block diagram of a memory device according to an embodiment of the present disclosure.

FIG. 2 is an equivalent circuit diagram of a memory block illustrated in FIG. 1.

FIG. 3 is a diagram illustrating the structure of a page buffer circuit according to an embodiment of the present disclosure.

FIG. 4 is a diagram illustrating allocation of input/output paths of a page buffer circuit according to an embodiment of the present disclosure.

FIG. 5 is a diagram illustrating the disposition of local input/output lines according to an embodiment of the present disclosure.

FIG. 6 is a block diagram of a page buffer according to an embodiment of the present disclosure.

FIG. 7 is a diagram illustrating data output sections of page buffers according to an embodiment of the present disclosure.

FIG. 8 is a diagram illustrating data input/output paths according to an embodiment of the present disclosure.

FIG. 9 is a diagram illustrating the disposition of bit line contacts according to an embodiment of the present disclosure.

FIG. 10 and FIG. 11 are diagrams illustrating disposition of column decoder regions and contact open regions according to embodiments of the present disclosure.

FIG. 12 is a diagram illustrating the disposition of a page buffer circuit according to an embodiment of the present disclosure.

FIG. 13 is a diagram illustrating the disposition of bit line contacts according to an embodiment of the present disclosure.

FIG. 14 to FIG. 17 are diagrams illustrating the disposition of column decoder regions and contact open regions according to embodiments of the present disclosure.

FIG. 18 is a diagram illustrating the disposition of a page buffer circuit according to an embodiment of the present disclosure.

FIG. 19 is a diagram illustrating the disposition of local input/output lines according to an embodiment of the present disclosure.

FIG. 20 is a diagram illustrating the disposition of bit line contacts according to an embodiment of the present disclosure.

FIG. 21 is a diagram illustrating the disposition of a page buffer circuit according to an embodiment of the present disclosure.

FIG. 22 is a diagram illustrating the disposition of local input/output lines according to an embodiment of the present disclosure.

FIG. 23 is a diagram illustrating the disposition of bit line contacts according to an embodiment of the present disclosure.

FIG. 24 is a diagram illustrating the disposition of a page buffer circuit according to an embodiment of the present disclosure.

FIG. 25 is a diagram illustrating the disposition of local input/output lines according to an embodiment of the present disclosure.

FIG. 26 is a diagram illustrating the disposition of bit line contacts according to an embodiment of the present disclosure.

FIG. 27 is a diagram illustrating the structure of a page buffer circuit according to an embodiment of the present disclosure.

FIG. 28 is a diagram illustrating the disposition of a page buffer circuit according to an embodiment of the present disclosure.

FIG. 29 is a diagram illustrating the disposition of local input/output lines according to an embodiment of the present disclosure.

FIG. 30 is a diagram illustrating the disposition of a page buffer circuit according to an embodiment of the present disclosure.

FIG. 31 is a diagram illustrating the disposition of local input/output lines according to an embodiment of the present disclosure.

FIG. 32 and FIG. 33 are diagrams illustrating the disposition of page buffer circuits according to embodiments of the present disclosure.

FIG. 34 is a diagram illustrating the disposition of local input/output lines according to an embodiment of the present disclosure.

FIG. 35 to FIG. 37 are diagrams illustrating the disposition of page buffer circuits and disposition of local input/output lines according to the conventional art compared to the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element in between.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

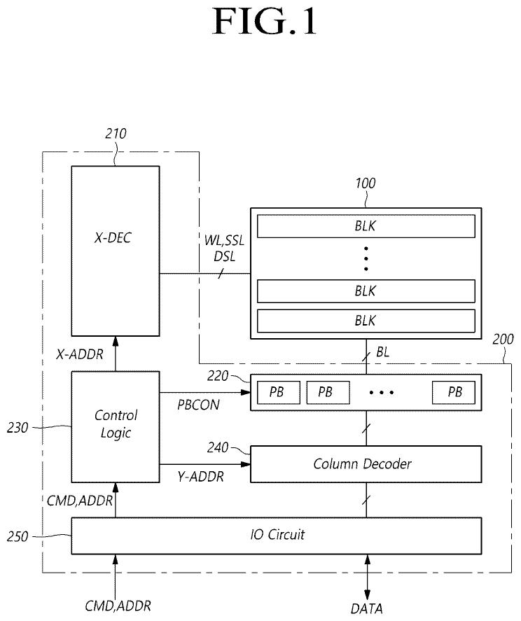

FIG. 1 is a block diagram of a memory device according to an embodiment of the present disclosure.

Referring to FIG. 1, a memory device according to an embodiment of the present disclosure may include a memory cell array 100 and a peripheral circuit 200. The peripheral circuit 200 may include a row decoder (X-DEC) 210, a page buffer circuit 220, a control logic 230, a column decoder 240 and an input/output circuit (IO circuit) 250.

The memory cell array 100 may include a plurality of memory cells. The memory cell array 100 may be configured as a three-dimensional memory array in which memory cells are stacked in a direction perpendicular to a substrate, but configurations not limited thereto.

The memory cell array 100 may be connected to the row decoder 210 through word lines WL and select lines DSL and SSL. The select lines DSL and SSL may include a drain select line DSL and a source select line SSL. The memory cell array 100 may be connected to the page buffer circuit 220 through bit lines BL. The memory cell array 100 may store data received through the page buffer circuit 220 in a program operation, and may transmit stored data to the page buffer circuit 220 in a read operation.

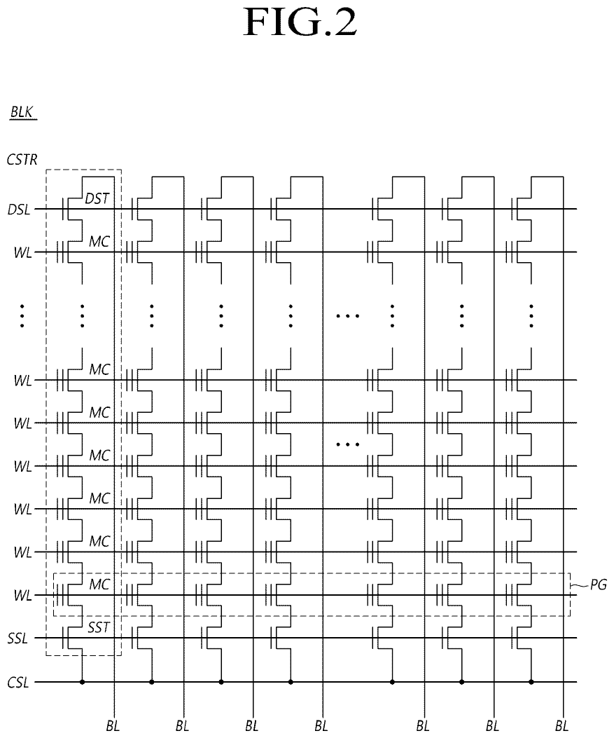

The memory cell array 100 may include a plurality of memory blocks BLK. Memory block BLK may be an erase unit. Word lines WL, select lines DSL and SSL and bit lines BL may be connected to each memory block BLK. Word lines WL and select lines DSL and SSL may be connected to a corresponding memory block BLK. Bit lines BL may be connected in common to a plurality of memory blocks BLK. An example of a memory block BLK will be described later with reference to FIG. 2.

The row decoder 210 may select one of the memory blocks BLK of the memory cell array 100 in response to a row address X-ADDR received from the control logic 230. The row decoder 210 may transmit operating voltages to word lines WL and select lines DSL and SSL connected to a selected memory block BLK.

The page buffer circuit 220 may include a plurality of page buffers PB that are connected to the bit lines BL, respectively. The page buffers PB may exchange data with the memory cell array 100 through the bit lines BL.

The page buffer circuit 220 may operate in response to a page buffer control signal PBCON that is received from the control logic 230. In a write operation, the page buffers PB may store data to be programmed to memory cells. The page buffers PB may apply voltages to the plurality of bit lines BL on the basis of the stored data. In a read operation or a verify read operation, the page buffers PB may sense voltages of the bit lines BL and store sensing results.

The control logic 230 may generate the page buffer control signal PBCON in response to a command CMD inputted through the input/output circuit 250. The control logic 230 may generate the row address X-ADDR and a column address Y-ADDR in response to an address ADDR inputted through the input/output circuit 250.

The column decoder 240 exchanges data with the page buffers PB in response to the column address Y-ADDR from the control logic 230.

The input/output circuit 250 may exchange data with the column decoder 240. The input/output circuit 250 may exchange data DATA with an external device, for example, a memory controller, through input/output paths, and may transmit the command CMD and the address ADDR received from the external device through the input/output paths, to the control logic 230. The input/output paths may include 2^{N} (where N is a natural number equal to or greater than 2) number of input/output pins. In an example, N=3, that is, input/output paths may include eight input/output pins (IO<0> to IO<7>).

The entirety or a part of the peripheral circuit 200 may be disposed on a plane different from the memory cell array 100. For example, the memory cell array 100 may be disposed in a first semiconductor layer, and the peripheral circuit 200 may be disposed in a second semiconductor layer that vertically overlaps the first semiconductor layer. A part or the entirety of the peripheral circuit 200 disposed in the second semiconductor layer may vertically overlap the memory cell array 100.

FIG. 2 is an equivalent circuit diagram of a memory block illustrated in FIG. 1.

Referring to FIG. 2, each memory block BLK may include a plurality of cell strings CSTR that are connected between a plurality of bit lines BL and a common source line CSL.

Each cell string CSTR may be connected between a corresponding bit line BL and the common source line CSL. Each cell string CSTR may include a source select transistor SST that is connected to the common source line CSL, a drain select transistor DST that is connected to the bit line BL, and a plurality of memory cells MC that are connected between the source select transistor SST and the drain select transistor DST. The gate of the source select transistor SST may be connected to a source select line SSL. The gates of the memory cells MC may each be connected to a corresponding word line WL. The gate of the drain select transistor DST may be connected to a drain select line DSL.

The source select line SSL, the word lines WL and the drain select line DSL may be extended in a direction perpendicular to the bit line BL. The source select line SSL, the word lines WL and the drain select line DSL may be stacked in a direction perpendicular to the surface of a substrate to form a three-dimensional structure.

Memory cells MC included in the memory block BLK may be divided into physical page units or logical page units. For example, memory cells that share one word line WL and are connected to different cell strings CSTR may form one physical page PG. Page PG may be the basic unit of a read operation.

For example, FIG. 2 illustrates that one drain select transistor DST and one source select transistor SST are provided in each cell string CSTR. However, two or more drain select transistors or two or more source select transistors may be provided in each cell string CSTR.

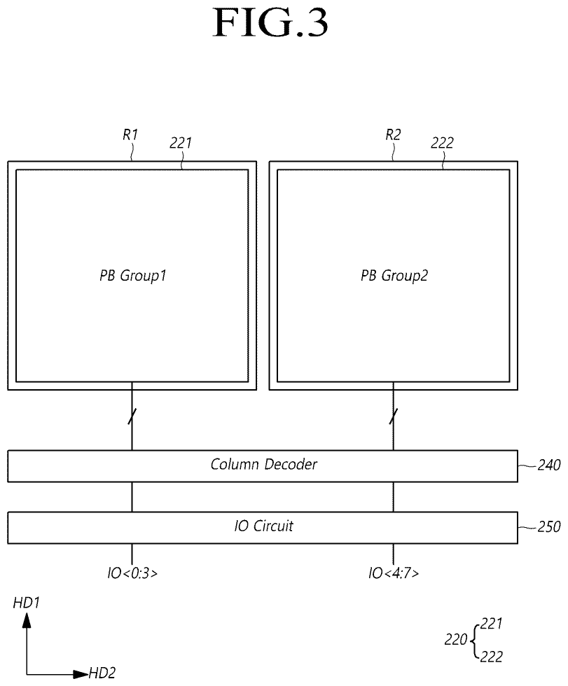

FIG. 3 is a diagram illustrating the structure of a page buffer circuit according to an embodiment of the present disclosure.

Referring to FIG. 3, input/output pins may be grouped into two groups. Input/output pins may include input/output pins IO<0:3> of a first group and input/output pins IO<4:7> of a second group. FIG. 3 illustrates eight input/output pins and thus the number of the input/output pins IO<0:3> of the first group and the number of the input/output pins IO<4:7> of the second group are four each, but in other embodiments the number of input/output pins may be more than eight. As the total number of input/output pins changes, the number of input/output pins included in each group also changes.

A page buffer circuit 220 includes a first page buffer group PB Group1 221 that is connected to the input/output pins IO<0:3> of the first group and a second page buffer group PB Group2 222 that is connected to the input/output pins IO<4:7> of the second group.

The first page buffer group 221 is connected to the input/output pins IO<0:3> of the first group through a column decoder 240 and an input/output circuit 250, and the second page buffer group 222 is connected to the input/output pins IO<4:7> of the second group through the column decoder 240 and the input/output circuit 250.

The first page buffer group 221 and the second page buffer group 222 are separated from each other, and are disposed in a first page buffer region R1 and a second page buffer region R2, respectively. The first page buffer region R1 and the second page buffer region R2 may be arranged in a second direction HD2 that is perpendicular to a first direction HD1.

The first direction HD1 is the extension direction of bit lines, and the second direction HD2 is the arrangement direction of the bit lines. In the present specification, the first direction HD1 may also be defined as a column direction, and the second direction HD2 may also be defined as a row direction.

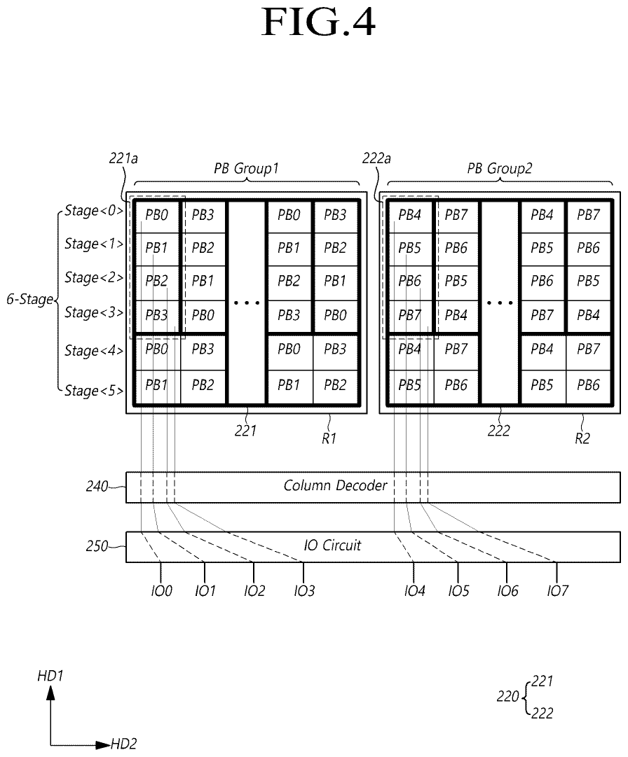

FIG. 4 is a diagram illustrating allocation of input/output paths of a page buffer circuit according to an embodiment of the present disclosure.

Referring to FIG. 4, a page buffer circuit 220 may be constituted by six stages (6-Stage). In FIG. 4, page buffers PB of the page buffer circuit 220 constituted by the six stages (6-Stage) are disposed in six rows in the first direction HD1.

The number # of a page buffer PB # indicates to which input/output pin the page buffer PB # is connected. For example, a page buffer PB0 is connected to an input/output pin IO<0>, and a page buffer PB2 is connected to an input/output pin IO<2>. Each of page buffers PB of a first page buffer region R1 is connected to one of input/output pins IO<0> to IO<3> of a first group, and each of page buffers PB of a second page buffer region R2 is connected to one of input/output pins IO<4> to IO<7> of a second group.

Page buffers PB are disposed in six stages in the first direction HD1 in the first page buffer region R1, and the input/output pins IO<0:3> of the first group may be allocated sequentially in the first direction HD1. Page buffers PB are disposed in six stages in the first direction HD1 in the second page buffer region R2, and the input/output pins IO<4:7> of the second group may be allocated sequentially in the first direction HD1.

Four among the page buffers PB belonging to the first page buffer region R1 and four among the page buffers PB belonging to the second page buffer region R2 may be simultaneously allocated to the eight input/output pins IO<0:7> to constitute a single page buffer input/output unit. For example, in FIG. 4, four page buffers PB0, PB1, PB2 and PB3 included in a dotted box 221a in the first page buffer region R1 and four page buffers PB4, PB5, PB6 and PB7 included in a dotted box 222a in the second page buffer region R2 may constitute a single page buffer input/output unit.

Among the page buffers PB in the first page buffer region R1, four page buffers PB belonging to a single page buffer input/output unit may constitute a first page buffer input/output sub unit. For example, the four page buffers PB0, PB1, PB2 and PB3 included in the dotted box 221a may constitute one first page buffer input/output sub unit. Among the page buffers PB in the second page buffer region R2, four page buffers PB belonging to a single page buffer input/output unit may constitute a second page buffer input/output sub unit. For example, the four page buffers PB4, PB5, PB6 and PB7 included in the dotted box 222a may constitute one second page buffer input/output sub unit.

A plurality of first page buffer input/output sub units are provided in the first page buffer region R1, a plurality of second page buffer input/output sub units are provided in the second page buffer region R2, and one of the plurality of first page buffer input/output sub units and one of the plurality of second page buffer input/output sub units constitute one page buffer input/output unit.

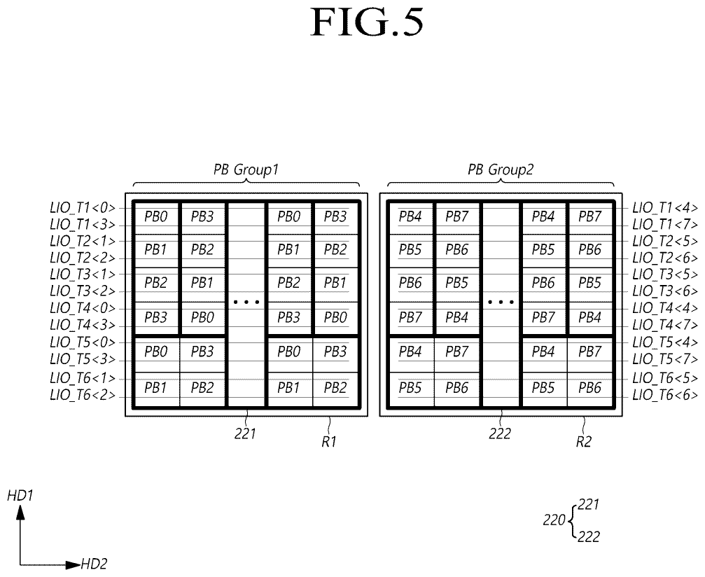

FIG. 5 is a diagram illustrating the disposition of local input/output lines according to an embodiment of the present disclosure. For example, FIG. 5 illustrates local input/output lines that are disposed in the first and second page buffer regions R1 and R2 of FIG. 4.

For the sake of simplicity in explanation, only local input/output lines are illustrated and described in the present specification, but inverted local input/output lines corresponding to the local input/output lines, respectively, may be further included. Description for local input/output lines applies the same to inverted local input/output lines.

Referring to FIG. 5, a plurality of local input/output lines LIO are disposed in each of the first and second page buffer regions R1 and R2. The local input/output lines LIO may extend in the second horizontal direction HD2 and may be disposed parallel to each other.

Among page buffers PB belonging to a single stage, page buffers PB connected to the same input/output pin are connected in common to one local input/output line LIO.

Because page buffers PB belonging to each stage in each of the first and second page buffer regions R1 and R2 are connected to two input/output pins, two local input/output lines LIO are disposed in each stage. In detail, in the first page buffer region R1, because the page buffer ‘PB0’ connected to the input/output pin IO0 and the page buffer ‘PB3’ connected to the input/output pin IO3 are disposed in each of stages Stage<0>, Stage<3> and Stage<4>, local input/output lines LIO<0> and LIO<3> corresponding to ‘0’ and ‘3’ are disposed in each of the stages Stage<0>, Stage<3> and Stage<4>. In the first page buffer region R1, because the page buffer ‘PB1’ connected to the input/output pin IO1 and the page buffer ‘PB2’ connected to the input/output pin IO2 are disposed in each of stages Stage<1>, Stage<2> and Stage<5>, local input/output lines LIO<1> and LIO<2> corresponding to ‘1’ and ‘2’ are disposed in each of the stages Stage<1>, Stage<2> and Stage<5>.

In the second page buffer region R2, because the page buffer ‘PB4’ connected to the input/output pin IO4 and the page buffer ‘PB7’ connected to the input/output pin IO7 are disposed in each of stages Stage<0>, Stage<3> and Stage<4>, local input/output lines LIO<4> and LIO<7> corresponding to ‘4’ and ‘7’ are disposed in each of the stages Stage<0>, Stage<3> and Stage<4>. In the second page buffer region R2, because the page buffer ‘PB5’ connected to the input/output pin IO5 and the page buffer ‘PB6’ connected to the input/output pin IO6 are disposed in each of stages Stage<1>, Stage<2> and Stage<5>, local input/output lines LIO<5> and LIO<6> corresponding to ‘5’ and ‘6’ are disposed in each of the stages Stage<1>, Stage<2> and Stage<5>.

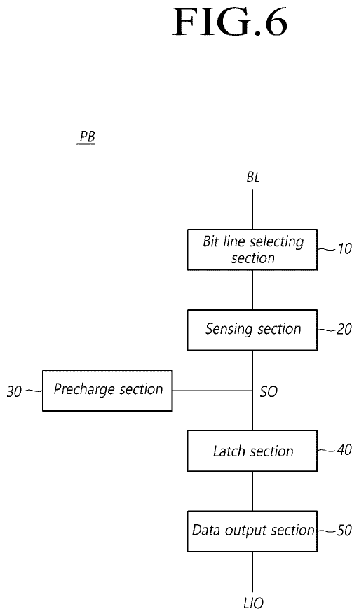

FIG. 6 is a block diagram of a page buffer according to an embodiment of the present disclosure.

Referring to FIG. 6, a page buffer PB includes a bit line selecting section 10, a sensing section 20, a precharge section 30, a latch section 40, and a data output section 50.

The bit line selecting section 10 is connected between a bit line BL and the sensing section 20, and electrically connects the bit line BL and the sensing section 20 in a read operation. The sensing section 20 is connected between the bit line selecting section 10 and a sensing node SO. The sensing section 20 connects the bit line BL connected through the bit line selecting section 10 in the read operation and the sensing node SO, and evaluates the sensing node SO on the basis of the current amount of the bit line BL. For example, the sensing section 20 lowers the potential of the sensing node SO from a precharged first level to a second level on the basis of the current amount of the bit line BL. The higher the current amount in the bit line BL, the shorter the time to lower the potential of the sensing node SO to the second level. That is to say, in a read operation, the level of the sensing node SO is lowered from the first level to the second level on the basis of the cell current of a selected memory cell connected to the bit line BL. The sensing node SO takes a shorter time to be lowered from the first level to the second level when the cell current amount of the selected memory cell is large, and takes a longer time to be lowered from the first level to the second level when the cell current amount of the selected memory cell is small.

The precharge section 30 is connected to the sensing node SO, precharges the bit line BL to a set level through the sensing section 20 and the bit line selecting section 10 in the read operation, and precharges the sensing node SO to the first level. The latch section 40 is connected to the sensing node SO, and latches data by sensing the potential level of the sensing node SO at regular intervals. The data output section 50 is connected between the output terminal of the latch section 40 and a local input/output line LIO, receives the data latched by the latch section 40, and outputs the data to the local input/output line LIO.

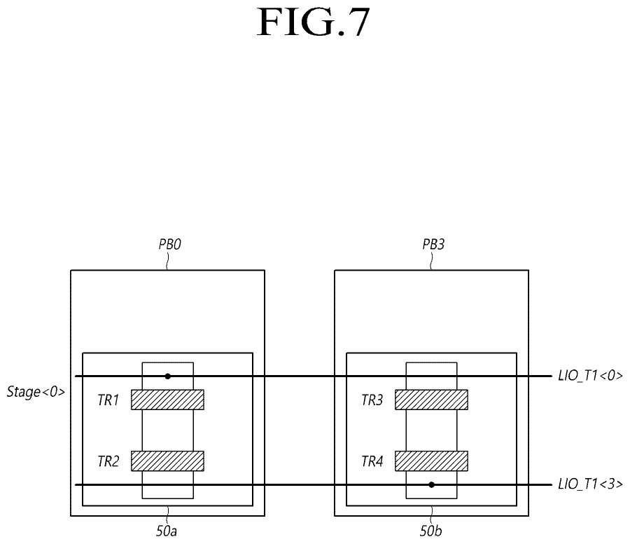

FIG. 7 is a diagram illustrating data output sections of page buffers according to an embodiment of the present disclosure. For example, FIG. 7 illustrates the data output sections of page buffers PB0 and PB3 included in stage Stage<0> of a first page buffer region R1.

Referring to FIG. 7, a page buffer PB may include data output transistors. The number of data output transistors is the same as the number of local input/output lines disposed in a stage of a page buffer region to which the page buffer PB belongs.

For example, when two local input/output lines LIO_T1<0> and LIO_T1<3> are disposed in the stage Stage<0> in the first page buffer region R1, each of a data output section 50a of the page buffer PB0 and a data output section 50b of the page buffer PB3 may include two data output transistors. In detail, the data output section 50a of the page buffer PB0 includes first and second data output transistors TR1 and TR2, and the data output section 50b of the page buffer PB3 includes third and fourth data output transistors TR3 and TR4. The first data output transistor TR1 is connected to the local input/output line LIO_T1<0>, and the fourth data output transistor TR4 is connected to the local input/output line LIO_T1<3>.

Because the number of data output transistors included in a page buffer PB is the same as the number of local input/output lines disposed in a stage of a page buffer region to which the page buffer PB belongs, when the number of local input/output lines disposed in the stage to which the page buffer PB belongs increases, the size of the page buffer PB may need to increase.

Embodiments of the present disclosure may group input/output pins into a first group and a second group, and may separate and dispose page buffers connected to input/output pins of the first group and page buffers connected to input/output pins of the second group in different regions. Therefore, the number of local input/output lines disposed in each stage in each page buffer region may be reduced, whereby the number of data output transistors included in a page buffer may be reduced and the size of the page buffer may be reduced.

For the sake of simplicity in explanation, FIG. 7 illustrates only local input/output lines and data output transistors, but inverted local input/output lines corresponding to the local input/output lines and inverted data output transistors corresponding to the data output transistors may be further included.

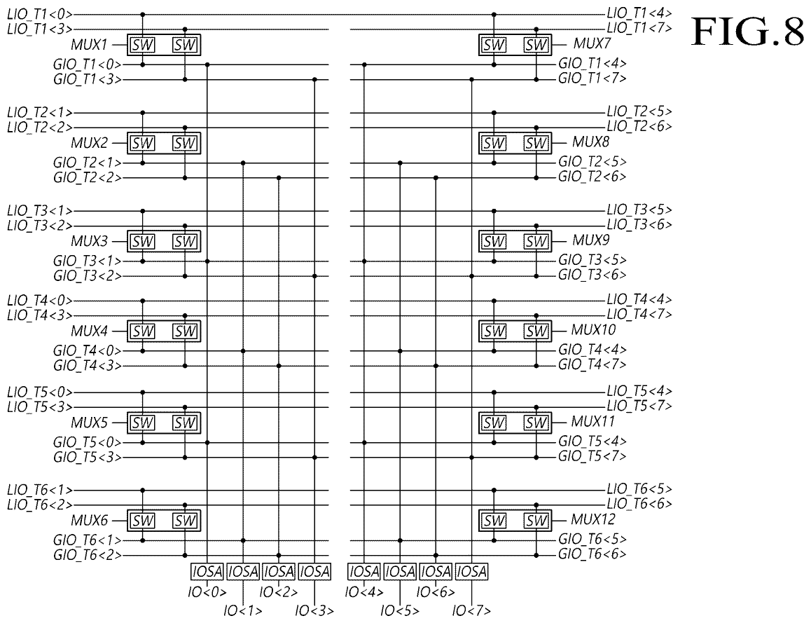

FIG. 8 is a diagram illustrating data input/output paths according to an embodiment of the present disclosure.

Referring to FIG. 8, each local input/output line LIO is connected to a corresponding switch circuit SW, and is connected to a corresponding global input/output line GIO through the switch circuit SW. One multiplexer MUX may include two switch circuits SW, and multiplexers MUX may be included in a column decoder 240 of FIG. 1.

Each of global input/output lines GIO is connected to a corresponding input/output sense amplifier IOSA. Among the global input/output lines, global input/output lines GIO that are connected in common to one input/output pin IO are connected to each other before they are connected to an input/output sense amplifier IOSA, and may be connected in common to the input/output sense amplifier IOSA in the state in which they are connected to each other.

An input/output circuit 250 (see FIG. 1) may include a plurality of input/output sense amplifiers IOSA, and each input/output sense amplifier IOSA is connected to one input/output pin IO.

In a data output operation, in response to the column address Y-ADDR (see FIG. 1), one multiplexer is selected from among a multiplexer MUX1 connected to local input/output lines LIO_T1<0,3>, a multiplexer MUX4 connected to local input/output lines LIO_T4<0,3> and a multiplexer MUX5 connected to local input/output lines LIO_T5<0,3>; one multiplexer is selected from among a multiplexer MUX2 connected to local input/output lines LIO_T2<1,2>, a multiplexer MUX3 connected to local input/output lines LIO_T3<1,2> and a multiplexer MUX6 connected to local input/output lines LIO_T6<1,2>; one multiplexer is selected from among a multiplexer MUX7 connected to local input/output lines LIO_T1<4,7>, a multiplexer MUX10 connected to local input/output lines LIO_T4<4,7> and a multiplexer MUX11 connected to local input/output lines LIO_T5<4,7>; and one multiplexer is selected from among a multiplexer MUX8 connected to local input/output lines LIO_T2<5,6>, a multiplexers MUX9 connected to local input/output lines LIO_T3<5,6> and a multiplexer MUX12 connected to local input/output lines LIO_T6<5,6>. Switch circuits SW included in four selected multiplexers MUX are turned on during a selection period, and local input/output lines LIO and global input/output lines GIO connected to the turned-on switch circuits SW are electrically connected to each other. Switch circuits SW included in unselected multiplexers MUX are turned off, and local input/output lines connected to the turned-off switch circuits SW are electrically isolated from global input/output lines.

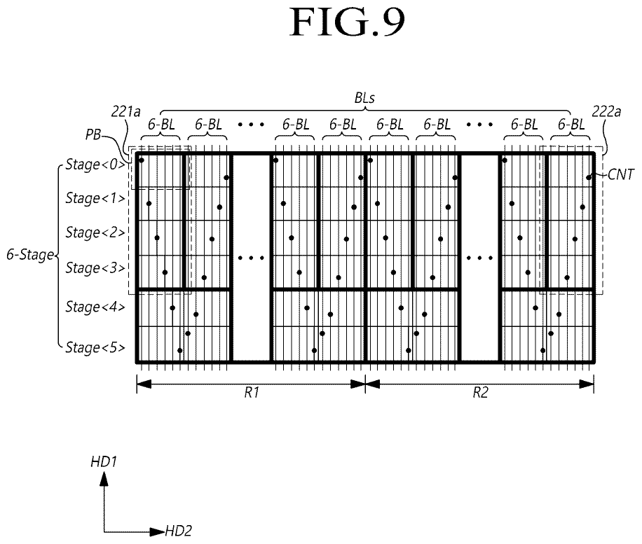

FIG. 9 is a diagram illustrating the disposition of bit line contacts according to an embodiment of the present disclosure. By way of example, FIG. 9 illustrates the disposition of bit line contacts in a page buffer circuit of FIG. 4.

Referring to FIG. 9, page buffers PB may be disposed in six stages 6-Stage, and six bit lines 6-BL may be disposed in each column of the first and second page buffer regions R1 and R2. Each page buffer PB is connected to a corresponding bit line BL through a bit line contact CNT.

Bit line contacts CNT may be disposed in a diagonal direction in one column. For example, in a first column, as a page buffer PB is disposed at a farther downward location in a direction opposite to the first direction HD1, a bit line contact CNT may be disposed at a location that is successively farther away in the second direction HD2. In addition, in a second column, as a page buffer PB is disposed at a farther upward location in the first direction HD1, a bit line contact CNT may be disposed at a location that is successively farther away in the second direction HD2. When the disposition of bit line contacts is repeated as described above among two adjacent columns of page buffers, the shape formed by the bit line contacts in the first and second columns repeatedly formed a V shape.

In each of the first and second page buffer regions R1 and R2, bit lines BL that are connected to page buffers PB belonging to a single page buffer input/output sub unit (indicated by a bold box) are disposed to neighbor each other.

When bit line contacts CNT are disposed in a V shape, the four bit lines (hereinafter referred to as a “bit line input/output sub unit”) connected to the bit line contacts CNT in a single page buffer input/output sub unit in each of the first and second page buffer regions R1 and R2 may be disposed consecutively.

Unlike the present disclosure, when four bit lines belonging to a single bit line input/output sub unit are not disposed consecutively, a defective particle that occurs at the boundary of two neighboring bit line input/output sub units may cause defects in both of the two bit line input/output sub units. In other words, when bit lines belonging to the same bit line input/output sub unit are not disposed consecutively, the probability that defects occur in two adjacent bit line input/output sub units, when a defective particle occurs at or near the boundary between the bit line input/output sub units, may increase.

According to an embodiment of the present disclosure, because four bit lines belonging to a single bit line input/output sub unit are disposed consecutively, it is possible to decrease the probability of a defect occurring in a bit line input/output unit due to a defective particle.

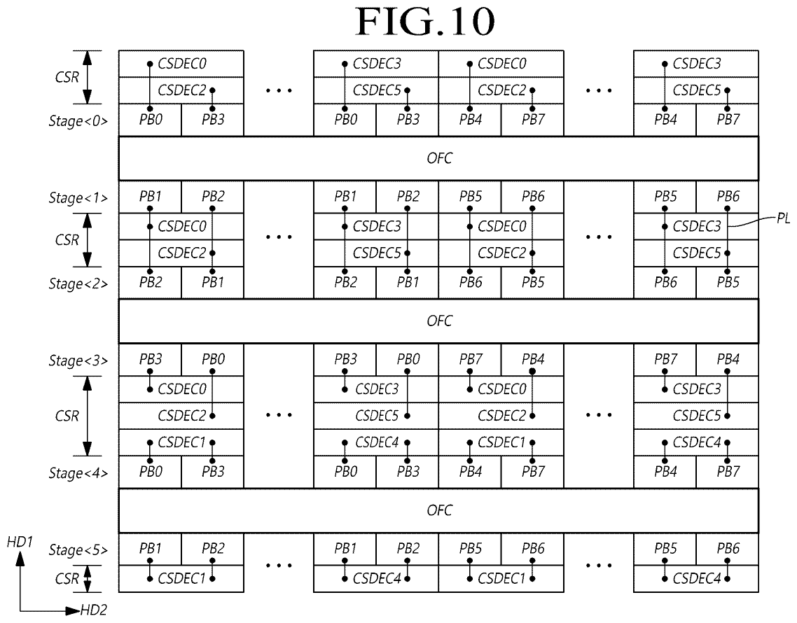

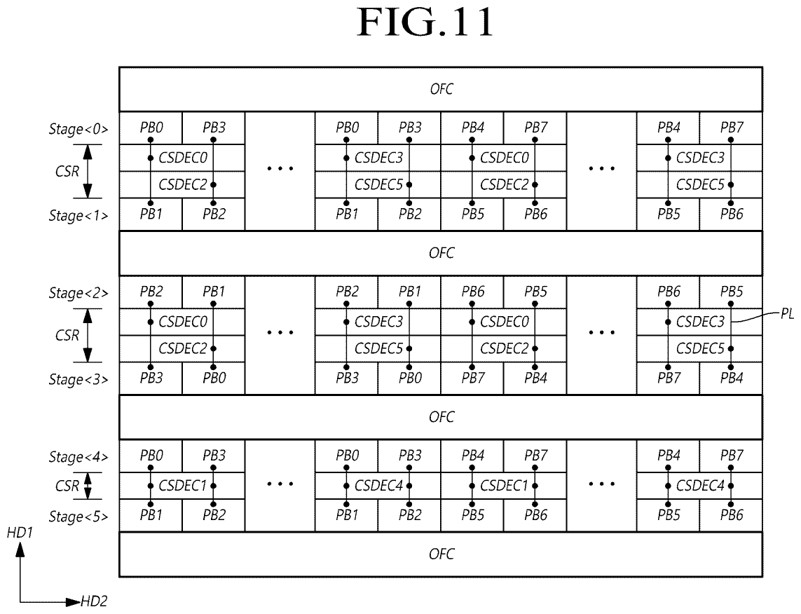

FIG. 10 and FIG. 11 are diagrams illustrating disposition of column decoder regions and contact open regions according to embodiments of the present disclosure. By way of example, FIG. 10 and FIG. 11 illustrate the disposition of column decoder regions and contact open regions related to a page buffer circuit of FIG. 4.

Referring to FIG. 10, a plurality of column decoder regions CSR are arranged in the first direction HD1. A plurality of column decoders CSDEC are disposed in the column decoder regions CSR. The plurality of column decoders CSDEC constitute a column decoder circuit 240 (see FIG. 1).

One of odd-numbered stages and one of even-numbered stages of the page buffer circuit (e.g., PB0 and PB1) are disposed between two column decoder regions CSR neighboring in the first direction HD1 (e.g., CSR adjacent to Stages<0> and <1>) from among the column decoder regions CSR.

A column decoder CSDEC is connected to a page buffer PB neighboring in the first direction HD1 through a page line PL. The page line PL may extend in the first direction HD1. The dimension of the column decoder CSDEC in the second direction HD2 is larger than the dimension of the page buffer PB in the second direction HD2. For example, the dimension of the column decoder CSDEC in the second direction HD2 may be twice the dimension of the page buffer PB in the second direction HD2.

A contact open region OFC is disposed, in the first direction HD1, between an odd-numbered stage and an even-numbered stage of the page buffer circuit, which in turn are located between two column decoder regions CSR.

Bit line contacts (not illustrated) that connect page buffers PB and bit lines may be disposed in the contact open region OFC. Bit line contacts connected to the page buffers PB of an odd-numbered stage and an even-numbered stage disposed on both sides of one contact open region OFC may be disposed in that contact open region OFC. For example, two adjacent stages (e.g., Stages<0> and <1>) share one contact open region OFC located directly between the two adjacent stages.

In FIG. 10, the number of contact open regions OFC is three and the number of column decoder regions CSR is four. Because the number of contact open regions OFC not used in disposition of circuits is smaller than the number of column decoder regions CSR, more of the area of a substrate available for disposition of circuits is used.

Referring to FIG. 11, a plurality of contact open regions OFC are arranged in the first direction HD1.

One of odd-numbered stages and one of even-numbered stages of the page buffer circuit are disposed between two contact open regions OFC neighboring each other in the first direction HD1.

Two stages neighboring each other with one contact open region OFC interposed therebetween share the one contact open region OFC. Each of an uppermost stage Stage<0> and a lowermost stage Stage<5>, however, does not share a contact open region OFC with another stage.

One column decoder region CSR is disposed between an odd-numbered stage and an even-numbered stage of the page buffer circuit, and both stages and the column decoder region CSR may be disposed between two contact open regions OFC.

Each of column decoders CSDEC that are disposed in the column decoder region CSR is connected to page buffers PB neighboring in the first direction HD1 through a page line PL.

One of page buffers PB of an odd-numbered stage and one of page buffers PB of an even-numbered stage are connected in common to one column decoder CSDEC to share the one column decoder CSDEC. In the present embodiment, in all stages, a page buffer PB shares a column decoder CSDEC with another page buffer PB.

Because all page buffers PB share column decoders CSDEC with other page buffers PB, compared to a case where there is a page buffer PB that does not share a column decoder CSDEC with another page buffer PB, the number of column decoders CSDEC may be reduced and the size of a column decoder circuit 240 (see FIG. 1) may be reduced. Because the column decoder circuit 240 (see FIG. 1) may be configured in a smaller size, the available area for disposing other circuits excluding the column decoder circuit 240 (see FIG. 1) may be increased.

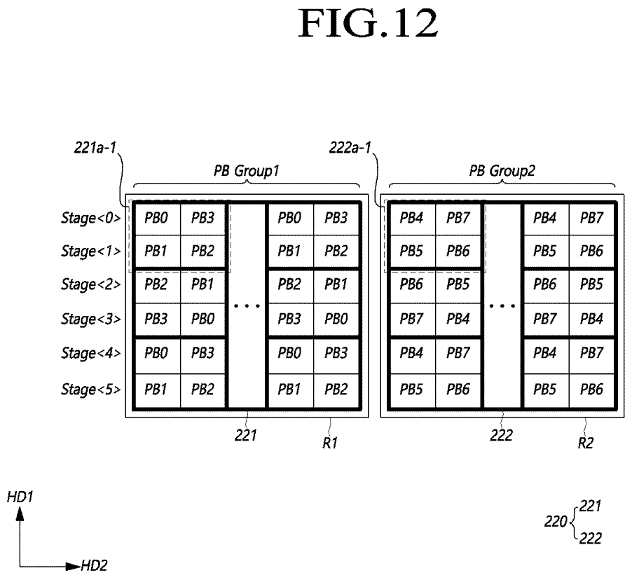

FIG. 12 is a diagram illustrating the disposition of a page buffer circuit according to an embodiment of the present disclosure.

Referring to FIG. 12, page buffers PB are disposed in a first page buffer region R1 and six stages arranged in the first direction HD1, and four page buffers PB that are included in one first page buffer input/output sub unit 221a-1 are disposed in a 2×2 matrix form in the first direction HD1 and the second direction HD2.

Page buffers PB are disposed in a second page buffer region R2 and six stages arranged in the first direction HD1, and four page buffers PB that are included in one second page buffer input/output sub unit 222a-1 are disposed in a 2×2 matrix form in the first direction HD1 and the second direction HD2. Because disposition of local input/output lines is the same as that in FIG. 5, a duplicate description is omitted here.

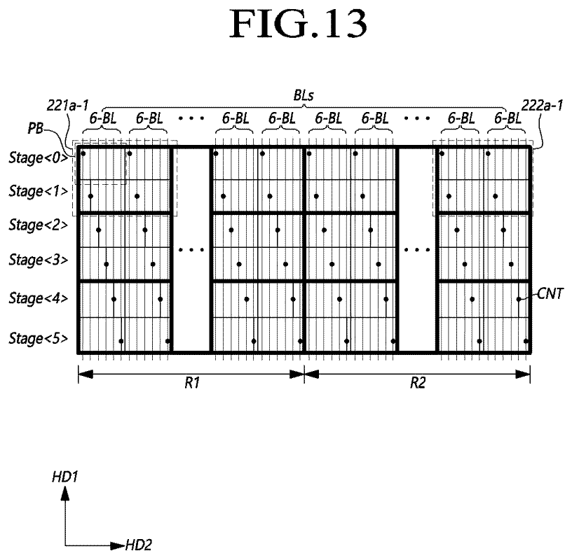

FIG. 13 is a diagram illustrating the disposition of bit line contacts according to an embodiment of the present disclosure. By way of example, FIG. 13 illustrates disposition of bit line contacts in a page buffer circuit of FIG. 12.

Referring to FIG. 13, bit line contacts CNT may be disposed in a diagonal line shape that extends in the same direction in all columns. Such disposition of bit line contacts CNT may be defined as disposition in a unidirectional diagonal line shape. Two bit lines BL that are respectively connected to two page buffers PB neighboring each other in the first direction HD1 are disposed to directly next to each other.

Due to the unidirectional diagonal disposition of bit line contacts CNT in a six bit line 6-BL column, bit line contacts CNT in the same row (i.e., the same stage) may be disposed not to neighbor each other. As the degree of integration of memory devices increases, the spacing between bit lines BL is getting narrower. In this situation, when two bit line contacts CNT neighbor each other in the same row, there is a high possibility that a defect will occur in which the two bit line contacts CNT are short-circuited. When bit line contacts CNT are disposed in a unidirectional diagonal line shape in a six bit lines 6-BL column as in FIG. 13, a defect in which bit line contacts CNT are short-circuited with each other may be reduced.

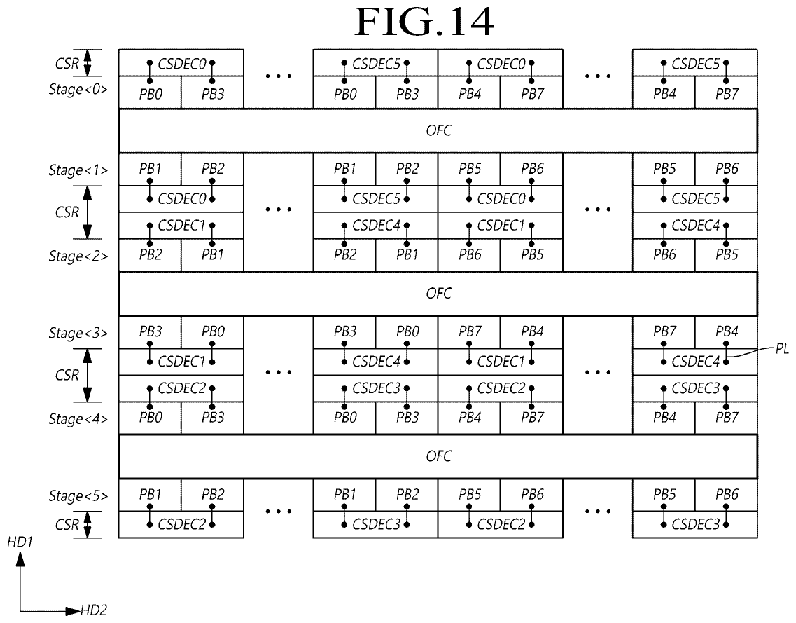

FIG. 14 to FIG. 17 are diagrams illustrating the disposition of column decoder regions and contact open regions according to embodiments of the present disclosure. By way of example, FIG. 14 to FIG. 17 illustrate the disposition of column decoder regions and contact open regions related to the page buffer circuit of FIG. 12.

Referring to FIG. 14, rows of column decoder regions CSR are arranged in the first direction HD1.

Two stages are disposed between two column decoder regions CSR that are adjacent in the first direction HD1. Four page buffers PB belonging to a single page buffer input/output sub unit 221a-1 or 222a-1 (see FIG. 12) are disposed in a 2×2 matrix form between two neighboring column decoder regions CSR.

Because four page buffers PB belonging to a single page buffer input/output sub unit 221a-1 or 222a-1 (see FIG. 12) are disposed between two neighboring column decoder regions CSR, a column decoder CSDEC and a page buffer PB that are connected to each other through a page line PL may be disposed to neighbor each other in the first direction HD1.

A page line PL extends in the first direction HD1, and may have a short length that connects a column decoder CSDEC and a page buffer PB that are adjacent each other.

One contact open region OFC is disposed between two stages that are, in turn, disposed between two neighboring column decoder regions CSR. Bit line contacts connected to page buffers PB of two stages located on both sides of one contact open region OFC may be disposed in the one contact open region OFC. Therefore, page buffers PB of two stages disposed on both sides of one contact open region OFC may share the one contact open region OFC.

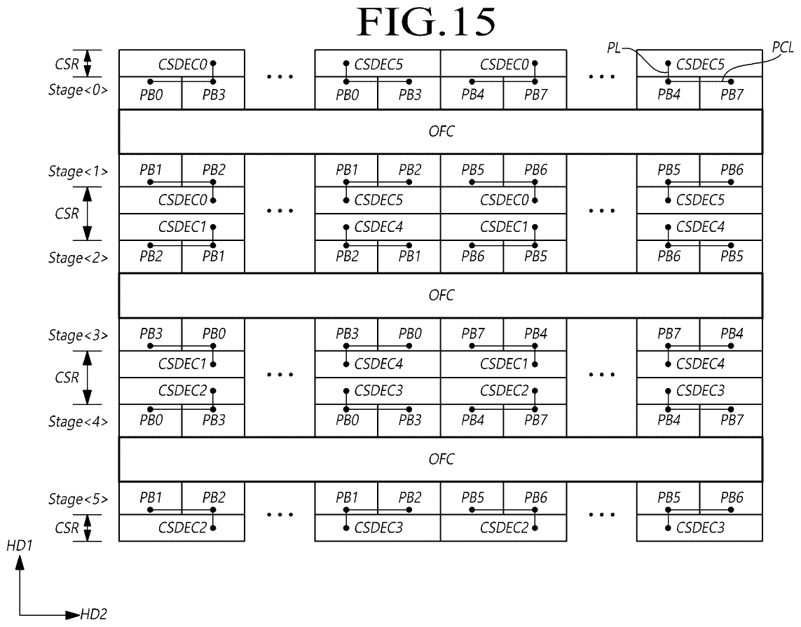

Referring to FIG. 15, two page buffers PB adjacent to the same column decoder CSDEC in the first direction HD1. A first page buffer PB among the two page buffers PB may be connected to the column decoder CSDEC through a page line PL. A second page buffer PB among the two page buffers PB may be connected to the column decoder CSDEC using a page connection line PCL that connects to the page line PL in the first page buffer PB. The page connection line PCL does not connect directly to the column decoder CSDEC.

The page connection line PCL may be disposed in a wiring layer different from a wiring layer in which the page line PL is disposed. Because the page line PL and the page connection line PCL that connect the page buffers PB and the column decoder CSDEC are disposed in different wiring layers, the number of wirings disposed in a single wiring layer may be reduced, and the spacing between neighboring wirings within the same layer may be increased to reduce interference between the wirings.

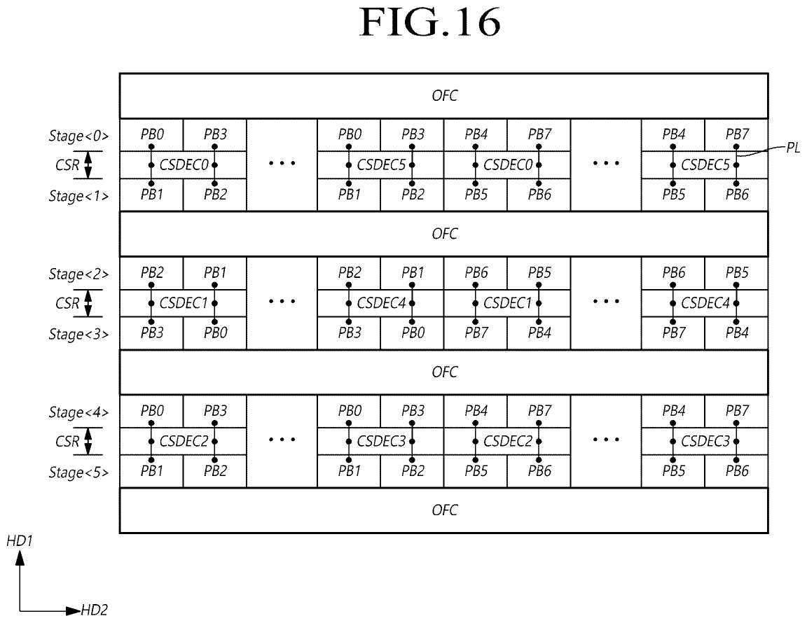

Referring to FIG. 16, a plurality of contact open regions OFC that extend in the second direction HD2 are arranged in the first direction HD1.

One of odd-numbered stages and one of even-numbered stages are disposed between two neighboring contact open regions OFC in the first direction HD1. Four page buffers PB belonging to a single page buffer input/output sub unit 221a-1 or 222a-1 (see FIG. 12) are disposed in a 2×2 matrix form between two neighboring contact open regions OFC.

One column decoder region CSR is disposed between two stages that are, in turn, disposed between two neighboring contact open regions OFC. Four page buffers PB included in a single page buffer input/output sub unit 221a-1 or 222a-1 (see FIG. 12) are divided such that two page buffers and are disposed each side, respectively, of one column decoder CSDEC in the first direction HD1.

A page buffer PB is connected to the column decoder CSDEC through a page line PL that extends in the first direction HD1. From a center of the column decoder CSDEC, the page line PL may extend in the first direction HD1 on both sides of the column decoder CSDEC so as to connect the column decoder CSDEC and a page buffer PB disposed on each side of the column decoder CSDEC.

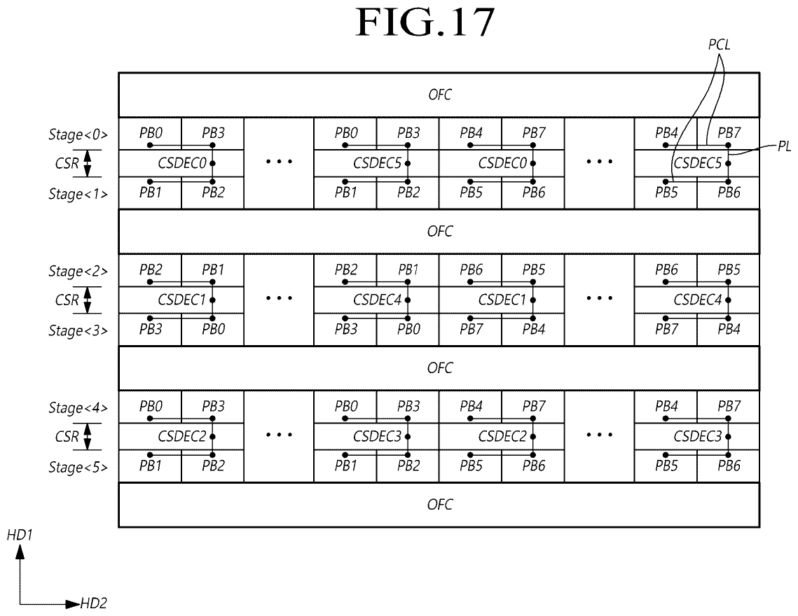

Referring to FIG. 17, a plurality of contact open regions OFC, page buffers PB, column decoders CSDEC and stages are disposed in substantially the same configuration as illustrated in FIG. 16 and therefore a duplicate description will not be included here. In FIG. 17, two of four page buffers PB that neighbor one column decoder CSDEC in the first direction HD1 may be connected to the column decoder CSDEC through a page line PL, and the other two may be connected to the page line PL via the page connection lines PCL. The page connection lines PCL do not connect directly to the column decoder CSDEC. The page connection lines PCL may be disposed in a different wiring layer other than a wiring layer in which the page line PL is disposed.

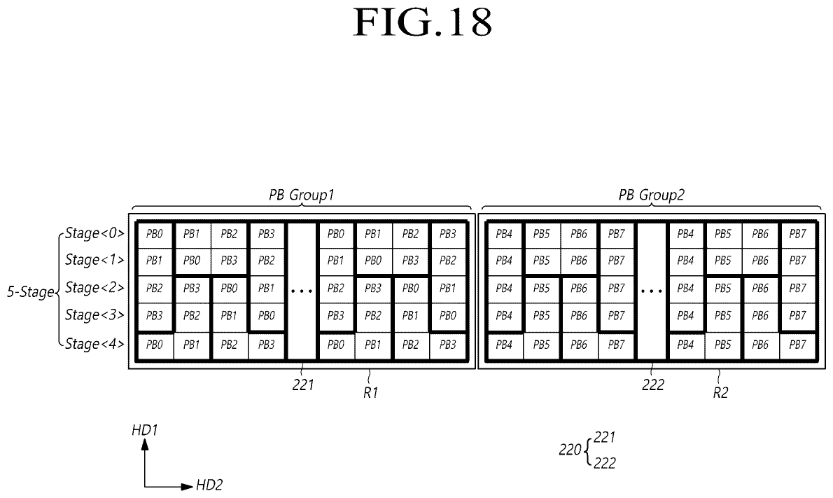

FIG. 18 is a diagram illustrating the disposition of a page buffer circuit according to an embodiment of the present disclosure.

Referring to FIG. 18, a page buffer circuit 220 may be constituted by five stages 5-Stage. Page buffers PB of the page buffer circuit 220 constituted by the five stages 5-Stage are disposed in five rows, which are arranged in the first direction HD1.

Page buffers PB are disposed in five stages in the first direction HD1 in a first page buffer region R1, and input/output pins IO<0:3> of a first group may be allocated sequentially in the first direction HD1. Similarly, page buffers PB are disposed in five stages in the first direction HD1 in a second page buffer region R2, and input/output pins IO<4:7> of a second group may be allocated sequentially in the first direction HD1.

Four among the page buffers PB of the first page buffer region R1 and four among the page buffers PB of the second page buffer region R2 may be simultaneously allocated to the eight input/output pins IO<0:7> to constitute one page buffer input/output unit.

Among the page buffers PB in the first page buffer region R1, four page buffers PB belonging to a single page buffer input/output unit, i.e., four page buffers PB0, PB1, PB2 and PB3 (outlined in bold in FIG. 18), may constitute a first page buffer input/output sub unit. Among the page buffers PB in the second page buffer region R2, four page buffers PB belonging to a single page buffer input/output unit, i.e., four page buffers PB4, PB5, PB6 and PB7 (outlined in bold in FIG. 18), may constitute a second page buffer input/output sub unit.

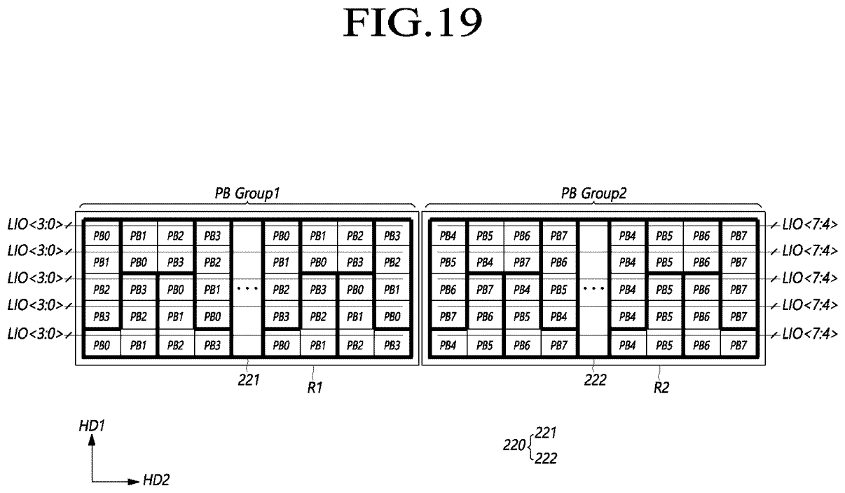

FIG. 19 is a diagram illustrating the disposition of local input/output lines according to an embodiment of the present disclosure. For example, FIG. 19 illustrates local input/output lines that are disposed in first and second page buffer regions R1 and R2 of FIG. 18.

Referring to FIG. 19, because page buffers PB disposed in each stage in each of the first and second page buffer regions R1 and R2 are connected to four input/output pins, four local input/output lines LIO are disposed in each stage.

For example, because page buffers ‘PB0,’ ‘PB1,’ ‘PB2’ and ‘PB3’ are disposed in each stage in the first page buffer region R1, local input/output lines LIO<0>, LIO<1>, LIO<2> and LIO<3>, which corresponding to ‘0,’ ‘1,’ ‘2’ and ‘3’, respectively, are disposed in each stage of the first page buffer region R1. Because page buffers ‘PB4,’ ‘PB5,’ ‘PB6’ and ‘PB7’ are disposed in each stage in the second page buffer region R2, local input/output lines LIO<4>, LIO<5>, LIO<6> and LIO<7> corresponding to ‘4,’ ‘5,’ ‘6’ and ‘7’ are disposed in each stage of the second page buffer region R2.

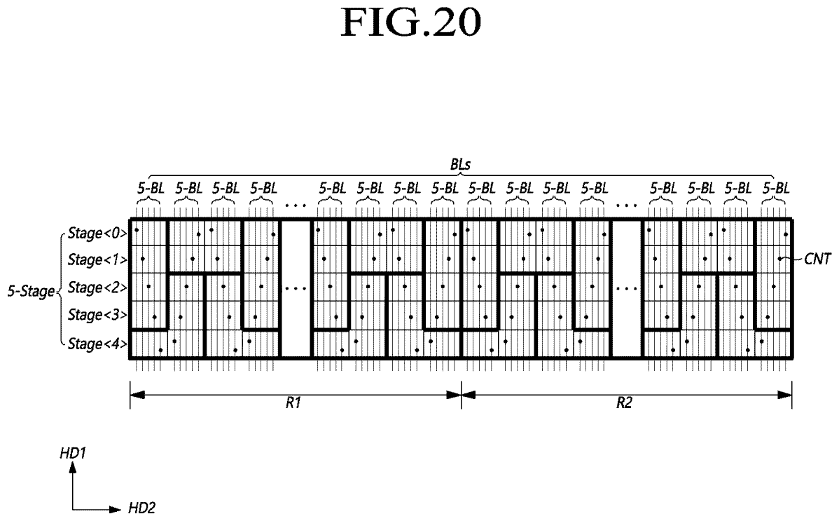

FIG. 20 is a diagram illustrating the disposition of bit line contacts according to an embodiment of the present disclosure. By way of example, FIG. 20 illustrates the disposition of bit line contacts in a page buffer circuit of FIG. 18.

Referring to FIG. 20, page buffers PB may be disposed in five stages 5-Stage, and five bit lines 5-BL may be disposed in each column of the first page buffer region R1 and the second page buffer region R2.

Each page buffer PB is connected to a bit line BL through a bit line contact CNT. Bit line contacts CNT may be disposed in a diagonal direction in within a five bit lines 5-BL column. For example, in a first column, as a page buffer PB is disposed at a farther downward location in a direction opposite to an uppermost page buffer PB in the first direction HD1, successive bit line contacts CNT may be disposed at a location that is farther away from the last in the second direction HD2. In addition, as in a second column, as a page buffer PB is disposed at a farther upward location a lowermost page buffer PB in the first direction HD1, a bit line contact CNT may be disposed at a location that is successively farther away in the second direction HD2. Thus, the bit line contacts CNT in adjacent five bit lines 5-BL columns may be arranged in a V shape.

In each of the first and second page buffer regions R1 and R2, bit lines BL that are connected to page buffers PB that belong to a single page buffer input/output sub unit and that neighbor each other are disposed to neighbor each other.

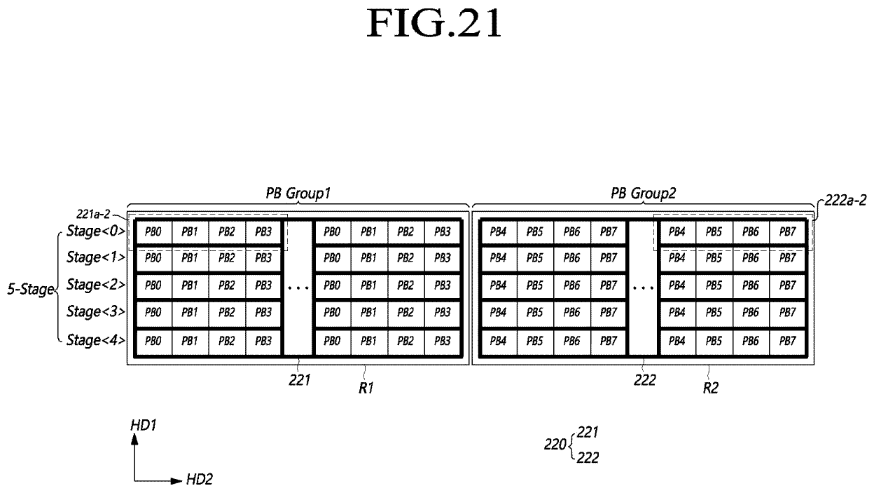

FIG. 21 is a diagram illustrating the disposition of a page buffer circuit according to an embodiment of the present disclosure.

Referring to FIG. 21, page buffers PB are disposed in a first page buffer region R1 and in five stages arranged in the first direction HD1, and input/output pins IO<0:3> of a first group may be allocated sequentially in the second direction HD2. Page buffers PB are disposed in a second page buffer region R2 and in five stages arranged in the first direction HD1, and input/output pins IO<4:7> of a second group may be allocated sequentially in the second direction HD2.

Page buffers PB belonging to a first page buffer input/output sub unit 221a-2 (i.e., page buffers PB surrounded by a bold line in the first page buffer region R1) are disposed in a line in the second direction HD2, and page buffers PB belonging to a second page buffer input/output sub unit 222a-2 (i.e., page buffers PB surrounded by a bold line in the second page buffer region R2) are disposed in a line in the second direction HD2.

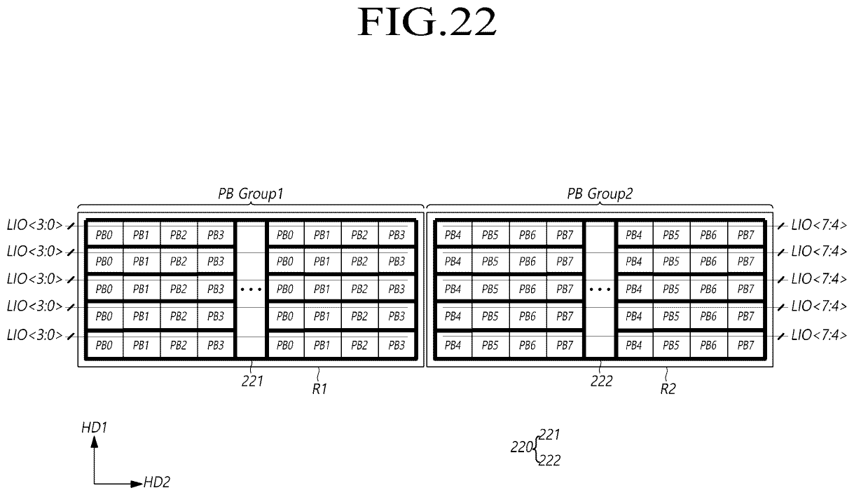

FIG. 22 is a diagram illustrating the disposition of local input/output lines according to an embodiment of the present disclosure. For example, FIG. 22 illustrates local input/output lines that are disposed in the first and second page buffer regions R1 and R2 of FIG. 21.

Referring to FIG. 22, because page buffers PB disposed in each stage in each of the first and second page buffer regions R1 and R2 are connected respectively to four input/output pins, four local input/output lines LIO are disposed in each stage.

In detail, because page buffers ‘PB0,’ ‘PB1,’ ‘PB2’ and ‘PB3’ are disposed in each stage in the first page buffer region R1, local input/output lines LIO<0>, LIO<1>, LIO<2> and LIO<3> are disposed in each stage of the first page buffer region R1. Because page buffers ‘PB4,’ ‘PB5,’ ‘PB6’ and ‘PB7’ are disposed in each stage in the second page buffer region R2, local input/output lines LIO<4>, LIO<5>, LIO<6> and LIO<7> are disposed in each stage of the second page buffer region R2.

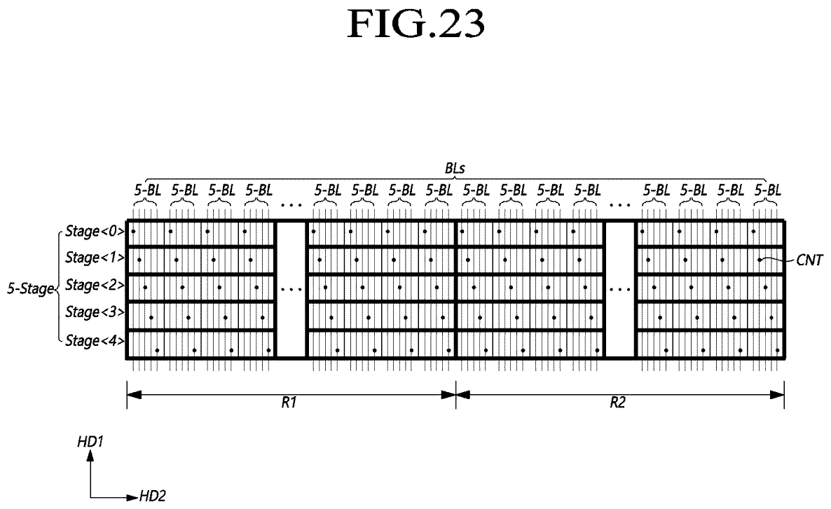

FIG. 23 is a diagram illustrating the disposition of bit line contacts according to an embodiment of the present disclosure.

Referring to FIG. 23, page buffers PB belonging to each of the first and second page buffer input/output sub units are disposed in a line in the second direction HD2, and bit line contacts CNT may be disposed in a unidirectional diagonal line shape in each column. In each column, two bit lines BL respectively connected to two page buffers PB neighboring each other in the first direction HD1 are disposed to be directly adjacent to each other, and bit line contacts CNT in one row (i.e., the same stage) may be arranged such that they are spaced apart rather than being directly adjacent.

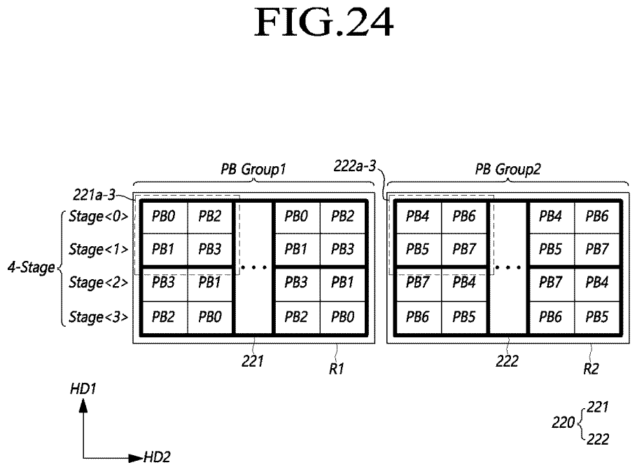

FIG. 24 is a diagram illustrating the disposition of a page buffer circuit according to an embodiment of the present disclosure.

Referring to FIG. 24, a page buffer circuit 220 may be constituted by four stages 4-Stage. Page buffers PB of the page buffer circuit 220 constituted by the four stages 4-Stage are disposed in four rows that are arranged in the first direction HD1.

Page buffers PB are disposed in a first page buffer region R1 and in four stages arranged in the first direction HD1, and four page buffers PB that are included in one first page buffer input/output sub unit 221a-3 are disposed in a 2×2 matrix form in the first direction HD1 and the second direction HD2. Page buffers PB are disposed in a second page buffer region R2 and in four stages arranged in the first direction HD1, and four page buffers PB that are included in one second page buffer input/output sub unit 222a-3 are disposed in a 2×2 matrix form in the first direction HD1 and the second direction HD2.

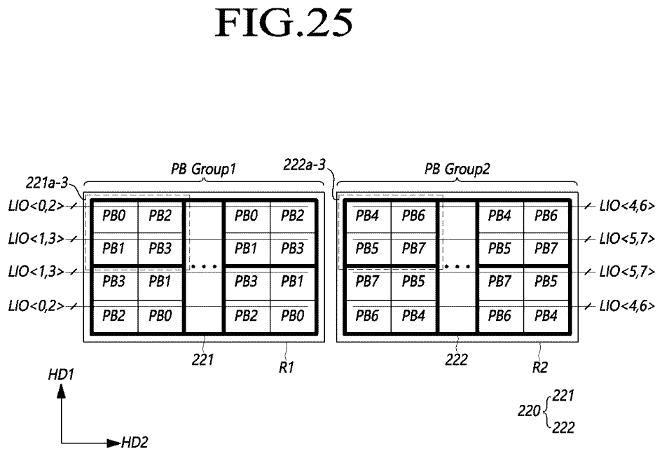

FIG. 25 is a diagram illustrating the disposition of local input/output lines according to an embodiment of the present disclosure. For example, FIG. 25 illustrates the disposition of local input/output lines that are disposed in the first and second page buffer regions R1 and R2 of FIG. 24.

Referring to FIG. 25, because page buffers PB disposed in each stage in each of the first and second page buffer regions R1 and R2 are connected to two input/output pins, two local input/output lines LIO are disposed in each stage.

In detail, in the first page buffer region R1, because page buffers ‘PB0’ and ‘PB2’ are disposed in each of stages Stage<0> and Stage<3>, local input/output lines LIO<0> and LIO<2> are disposed in each of the stages Stage<0> and Stage<3>. In the first page buffer region R1, because page buffers ‘PB1’ and ‘PB3’ are disposed in each of stages Stage<1> and Stage<2>, local input/output lines LIO<1> and LIO<3> are disposed in each of the stages Stage<1> and Stage<2>. In the second page buffer region R2, because page buffers ‘PB4’ and ‘PB6’ are disposed in each of stages Stage<0> and Stage<3>, local input/output lines LIO<4> and LIO<6> are disposed in each of the stages Stage<0> and Stage<3>. In the second page buffer region R2, because page buffers ‘PB5’ and ‘PB7’ are disposed in each of stages Stage<1> and Stage<2>, local input/output lines LIO<5> and LIO<7> are disposed in each of the stages Stage<1> and Stage<2>.

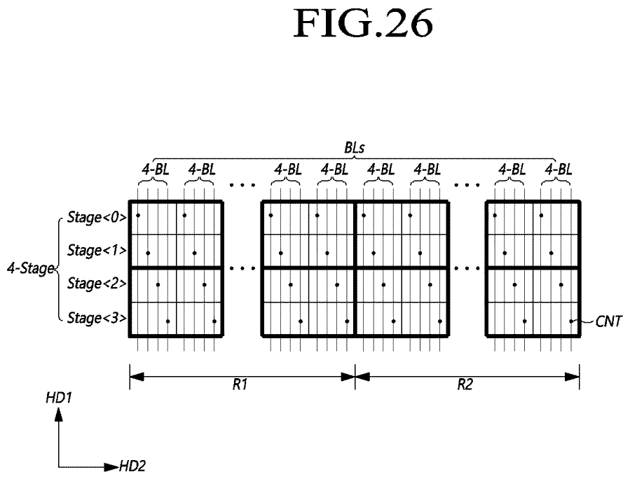

FIG. 26 is a diagram illustrating the disposition of bit line contacts according to an embodiment of the present disclosure. By way of example, FIG. 26 illustrates the disposition of bit line contacts in a page buffer circuit of FIG. 24.

Referring to FIG. 26, the page buffers PB may be disposed in the four stages 4-Stage, and four bit lines 4-BL may be disposed in each column of the first page buffer region R1 and the second page buffer region R2.

Each page buffer PB is connected to a bit line BL through a bit line contact CNT. Bit line contacts CNT may be disposed in a unidirectional diagonal line shape in all columns. In each column, two bit lines BL respectively connected to two page buffers PB neighboring each other in the first direction HD1 are disposed to be directly adjacent to each other, and bit line contacts CNT in a single row (i.e., the same stage) may be disposed not to be directly adjacent to each other.

In embodiments described above with reference to FIG. 3 to FIG. 26, page buffers connected to input/output pins of a first group are disposed in one first page buffer region and page buffers connected to input/output pins of a second group are disposed in one second page buffer region, but the present disclosure is not limited thereto. Page buffers connected to input/output pins of a first group may be disposed in a plurality of first page buffer regions, and page buffers connected to input/output pins of a second group may be disposed in a plurality of second page buffer regions. For example, the first page buffer regions and the second page buffer regions may be disposed alternately in the second direction HD2.

In embodiments described above with reference to FIG. 3 to FIG. 26, input/output pins are grouped into two groups, but the present disclosure is not limited thereto. In other embodiments, input/output pins may be grouped into four groups or other numbers of groups.

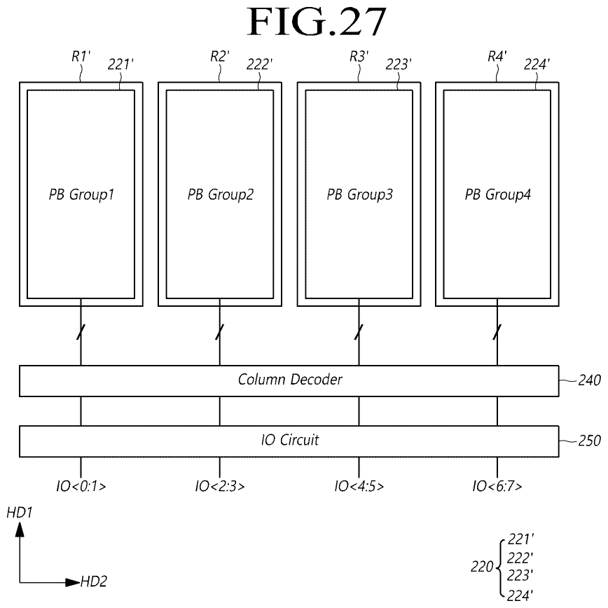

FIG. 27 is a diagram illustrating the structure of a page buffer circuit according to an embodiment of the present disclosure.

Referring to FIG. 27, input/output pins may be grouped into four groups. Input/output pins may include input/output pins IO<0:1> of a first group, input/output pins IO<2:3> of a second group, input/output pins IO<4:5> of a third group and input/output pins IO<6:7> of a fourth group. FIG. 27 illustrates eight input/output pins and two input/output pins belonging to each group, but when the total number of input/output pins changes, the number of input/output pins belonging to each group may also change to reflect the total number.

A page buffer circuit 220 includes a first page buffer group PB Group1 221′ connected to input/output pins IO<0:1> of a first group, a second page buffer group PB Group2, 222′ connected to input/output pins IO<2:3> of a second group, a third page buffer group PB Group3, 223′ connected to input/output pins IO<4:5> of a third group, and a fourth page buffer group PB Group4, 224′ connected to input/output pins IO<6:7> of a fourth group.

The first page buffer group 221′, the second page buffer group 222′, the third page buffer group 223′ and the fourth page buffer group 224′ may be separated from each other and be disposed in a first page buffer region R1′, a second page buffer region R2′, a third page buffer region R3′ and a fourth page buffer region R4′, respectively. The first, second, third and fourth page buffer regions R1′, R2′, R3′ and R4′ may be arranged in the second direction HD2.

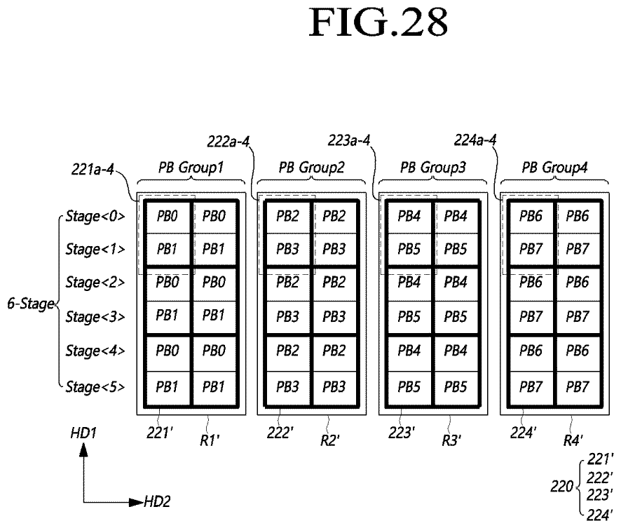

FIG. 28 is a diagram illustrating the disposition of a page buffer circuit according to an embodiment of the present disclosure.

Referring to FIG. 28, a page buffer circuit 220 may be constituted by six stages 6-Stage.

Page buffers PB are disposed in the first page buffer region R1′ and in six stages arranged in the first direction HD1, and the input/output pins IO<0:1> of a first group may be allocated sequentially in the first direction HD1. Page buffers PB are disposed in the second page buffer region R2′ and in six stages arranged in the first direction HD1, and the input/output pins IO<2:3> of a second group may be allocated sequentially in the first direction HD1. Page buffers PB are disposed in the third page buffer region R3′ and in six stages arranged in the first direction HD1, and the input/output pins IO<4:5> of a third group may be allocated sequentially in the first direction HD1. Page buffers PB are disposed in the fourth page buffer region R4′ and in six stages arranged in the first direction HD1, and the input/output pins IO<6:7> of the fourth group may be allocated sequentially in the first direction HD1.

Two page buffers PB belonging to the first page buffer region R1′, two page buffers PB belonging to the second page buffer region R2′, two page buffers PB belonging to the third page buffer region R3′ and two page buffers PB belonging to the fourth page buffer region R4′ may be simultaneously allocated to the eight input/output pins IO<0:7> to constitute one page buffer input/output unit. For example, in FIG. 28, two page buffers PB0 and PB1 included in a dotted box 221a-4 in the first page buffer region R1′, two page buffers PB2 and PB3 included in a dotted box 222a-4 in the second page buffer region R2′, two page buffers PB4 and PB5 included in a dotted box 223a-4 in the third page buffer region R3′ and two page buffers PB6 and PB7 included in a dotted box 224a-4 in the fourth page buffer region R4′ may constitute one page buffer input/output unit.

Two page buffers PB belonging to a single page buffer input/output unit among page buffers PB in the first page buffer region R1′ may constitute a first page buffer input/output sub unit, two page buffers PB belonging to the single page buffer input/output unit among page buffers PB in the second page buffer region R2′ may constitute a second page buffer input/output sub unit, two page buffers PB belonging to the single page buffer input/output unit among page buffers PB in the third page buffer region R3′ may constitute a third page buffer input/output sub unit, and two page buffers PB belonging to the single page buffer input/output unit among page buffers PB in the fourth page buffer region R4′ may constitute a fourth page buffer input/output sub unit.

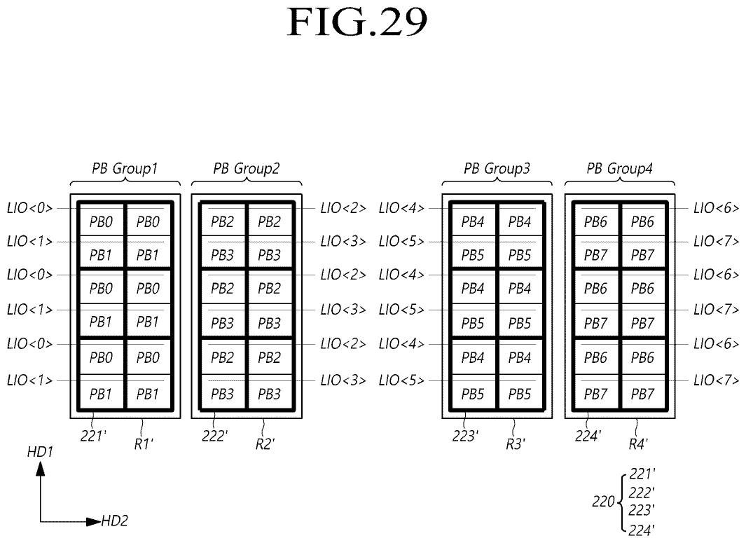

FIG. 29 is a diagram illustrating the disposition of local input/output lines according to an embodiment of the present disclosure. For example, FIG. 29 illustrates local input/output lines that are disposed in first, second, third and fourth page buffer regions R1′, R2′, R3′ and R4′ of FIG. 28.

Referring to FIG. 29, because page buffers PB disposed in each stage in each of the first, second, third and fourth page buffer regions R1′, R2′, R3′ and R4′ are connected to one input/output pin, one local input/output line LIO is disposed in each stage.

In detail, because page buffers ‘PB0’ are disposed in each of stages Stage<0>, Stage<2> and Stage<4> in the first page buffer region R1′, a local input/output line LIO<0> is disposed in each of the stages Stage<0>, Stage<2> and Stage<4>. Because page buffers ‘PB1’ are disposed in each of stages Stage<1>, Stage<3> and Stage<5> in the first page buffer region R1′, a local input/output line LIO<1> is disposed in each of the stages Stage<1>, Stage<3> and Stage<5>.

Local input/output lines are disposed also in the second, third and fourth page buffer regions R2′, R3′ and R4′ in a similar manner to the first page buffer region R1′.

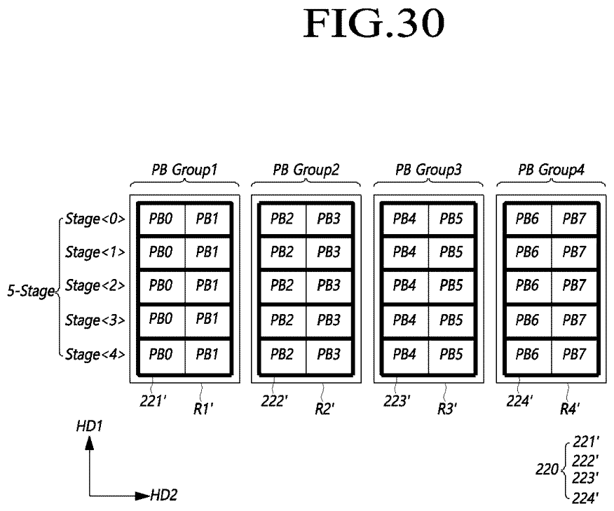

FIG. 30 is a diagram illustrating the disposition of a page buffer circuit according to an embodiment of the present disclosure.

Referring to FIG. 30, a page buffer circuit 220 may be constituted by five stages 5-Stage.

Page buffers PB are disposed in five stages arranged in the first direction HD1 in a first page buffer region R1′, and input/output pins IO<0:1> of a first group may be allocated sequentially in the first direction HD1. Page buffers PB are disposed in five stages in the first direction HD1 in a second page buffer region R2′, and input/output pins IO<2:3> of a second group may be allocated sequentially in the second direction HD2. Page buffers PB are disposed in five stages in the first direction HD1 in a third page buffer region R3′, and input/output pins IO<4:5> of a third group may be allocated sequentially in the second direction HD2. Page buffers PB are disposed in five stages in the first direction HD1 in a fourth page buffer region R4′, and input/output pins IO<6:7> of a fourth group may be allocated sequentially in the second direction HD2.

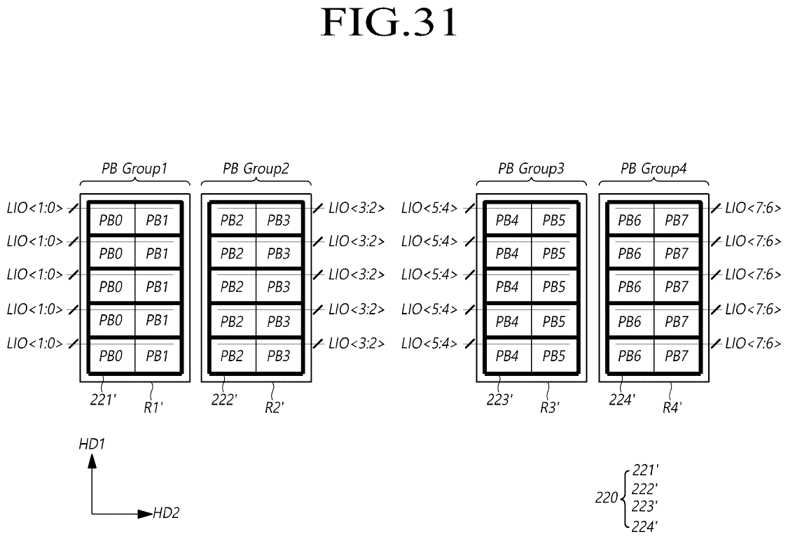

FIG. 31 is a diagram illustrating disposition of local input/output lines according to an embodiment of the present disclosure. For example, FIG. 31 illustrates local input/output lines that are disposed in first, second, third and fourth page buffer regions R1′, R2′, R3′ and R4′ of FIG. 30.

Referring to FIG. 31, because page buffers PB disposed in each stage in each of the first, second, third and fourth page buffer regions R1′, R2′, R3′ and R4′ are connected to two input/output pins, two local input/output lines LIO are disposed in each stage.

In detail, because page buffers ‘PB0’ and ‘PB1’ are disposed in each stage in the first page buffer region R1′, local input/output lines LIO<0> and LIO<1> are disposed in each stage. Local input/output lines are disposed also in the second, third and fourth page buffer regions R2′, R3′ and R4′ in a similar manner to the first page buffer region R1′.

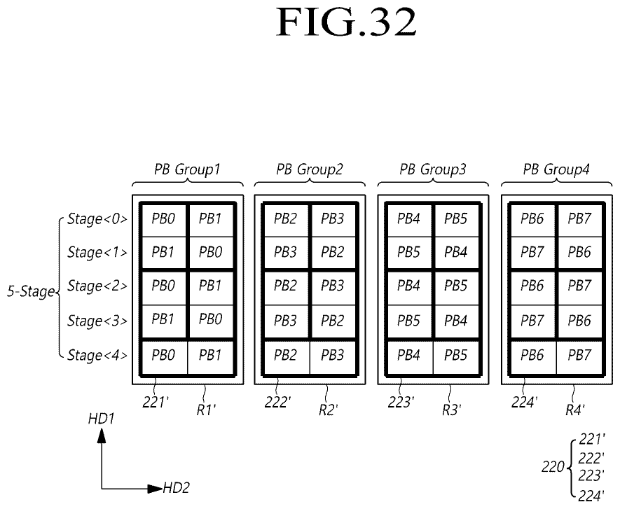

FIG. 32 is a diagram illustrating disposition of a page buffer circuit according to an embodiment of the present disclosure.

Referring to FIG. 32, a page buffer circuit 220 may be constituted by five stages 5-Stage.

Page buffers PB are disposed in a first page buffer region R1′ and in five stages arranged in the first direction HD1, and input/output pins IO<0:1> of a first group may be allocated sequentially in the first direction HD1. Page buffers PB are disposed in a second page buffer region R2′ and in five stages arranged in the first direction HD1, and input/output pins IO<2:3> of a second group may be allocated sequentially in the first direction HD1. Page buffers PB are disposed in a third page buffer region R3′ and in five stages arranged in the first direction HD1, and input/output pins IO<4:5> of a third group may be allocated sequentially in the first direction HD1. Page buffers PB are disposed in a fourth page buffer region R4′ and in five stages arranged in the first direction HD1, and input/output pins IO<6:7> of a fourth group may be allocated sequentially in the first direction HD1. Because disposition of local input/output lines is the same as that in FIG. 31, a duplicate description is omitted here.

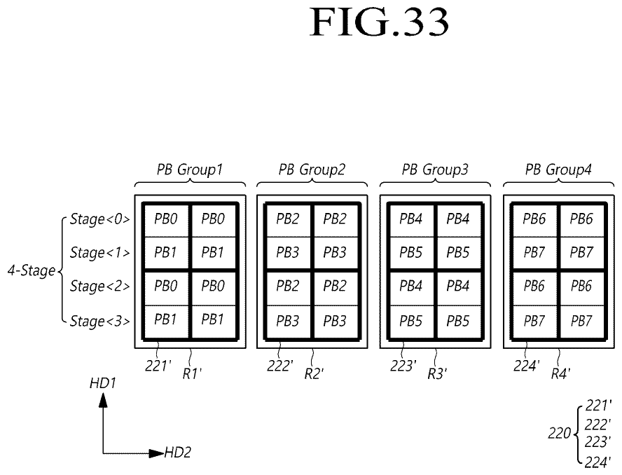

FIG. 33 is a diagram illustrating the disposition of a page buffer circuit according to an embodiment of the present disclosure.

Referring to FIG. 33, a page buffer circuit 220 may be constituted by four stages 4-Stage.

Page buffers PB are disposed in a first page buffer region R1′ and in four stages arranged in the first direction HD1, and input/output pins IO<0:1> of a first group may be allocated sequentially in the first direction HD1. Page buffers PB are disposed in a second page buffer region R2′ and in four stages arranged in the first direction HD1, and input/output pins IO<2:3> of a second group may be allocated sequentially in the first direction HD1. Page buffers PB are disposed in a third page buffer region R3′ and in four stages arranged in the first direction HD1, and input/output pins IO<4:5> of a third group may be allocated sequentially in the first direction HD1. Page buffers PB are disposed in a fourth page buffer region R4′ and in four stages arranged in the first direction HD1, and input/output pins IO<6:7> of a fourth group may be allocated sequentially in the first direction HD1.

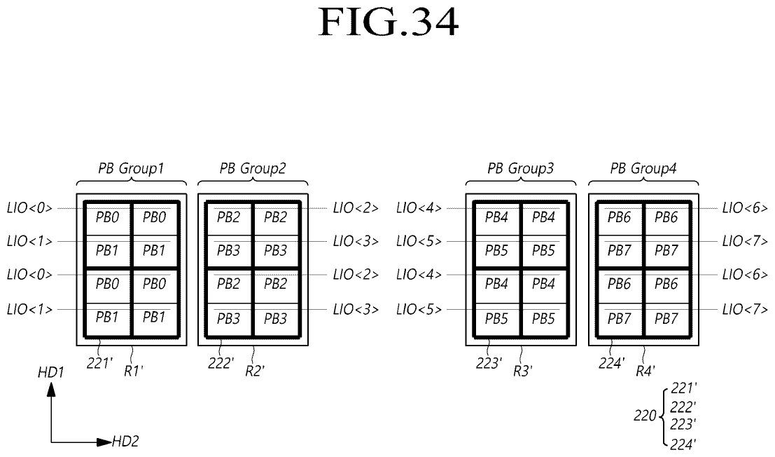

FIG. 34 is a diagram illustrating the disposition of local input/output lines according to an embodiment of the present disclosure. For example, FIG. 34 illustrates local input/output lines that are disposed in first, second, third and fourth page buffer regions R1′, R2′, R3′ and R4′ of FIG. 33.

Referring to FIG. 34, because page buffers PB disposed in each stage in each of the first, second, third and fourth page buffer regions R1′, R2′, R3′ and R4′ are connected to one input/output pin, one local input/output line LIO is disposed in each stage.

In detail, because page buffers ‘PB0’ are disposed in each of stages Stage<0> and Stage<2> in the first page buffer region R1′, a local input/output line LIO<0> is disposed in each of the stages Stage<0> and Stage<2>. Because page buffers ‘PB1’ are disposed in each of stages Stage<1> and Stage<3> in the first page buffer region R1′, a local input/output line LIO<1> is disposed in each of the stages Stage<1> and Stage<3>.

Local input/output lines are disposed also in the second, third and fourth page buffer regions R2′, R3′ and R4′ in a similar manner to the first page buffer region R1′.

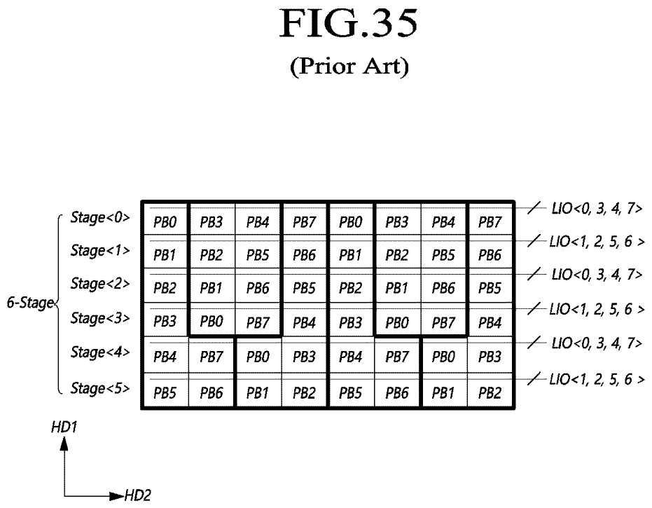

FIG. 35 to FIG. 37 are diagrams illustrating the disposition of page buffer circuits and disposition of local input/output lines according to the conventional art compared to the present disclosure.

Referring to FIG. 35, page buffers PB of a page buffer circuit are disposed in six stages arranged in the first direction HD1, and input/output pins IO<0:7> are allocated sequentially to the page buffers PB in the first direction HD1. The number of input/output pins that are connected to page buffers included in each stage is four, and four local input/output lines are disposed in each stage.

Referring to FIG. 5 again, according to an embodiment of the present disclosure, the number of input/output pins that are connected to page buffers PB included in each of the six stages in each of the first and second page buffer regions R1 and R2 is two, and two local input/output lines are disposed in each stage. The number of local input/output lines disposed in each stage is two, which is smaller than the number of local input/output lines according to the conventional art disclosed in FIG. 35.

Referring to FIG. 29 again, according to an embodiment of the present disclosure, the number of input/output pins that are connected to page buffers included in each of the six stages in each of the first, second, third and fourth page buffer regions R1′, R2′, R3′ and R4′ is one, and one local input/output line is disposed in each stage. The number of local input/output lines disposed in each stage is one, which is smaller than that according to the conventional art disclosed in FIG. 35.

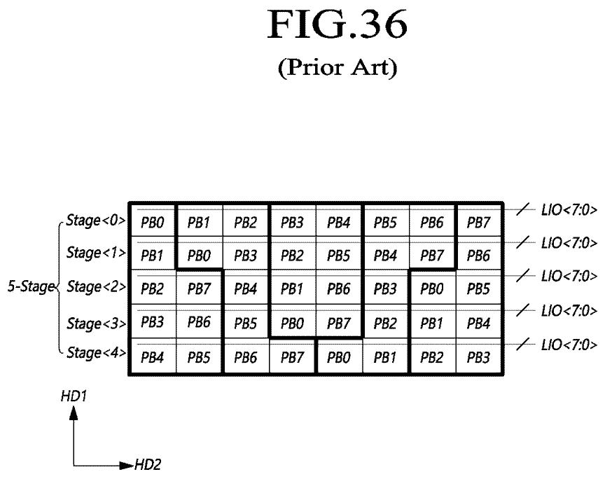

Referring to FIG. 36, page buffers PB of a page buffer circuit are disposed in five stages in the first direction HD1, and input/output pins IO<0:7> are allocated sequentially to the page buffers PB in the first direction HD1. The number of input/output pins that are connected to page buffers included in each stage is eight, and eight local input/output lines are disposed in each stage.

Referring to FIG. 19 and FIG. 22 again, according to embodiments of the present disclosure, the number of input/output pins that are connected to page buffers included in each of the five stages in each of the first and second page buffer regions R1 and R2 is four, and four local input/output lines are disposed in each stage. The number of local input/output lines disposed in each stage is four, which is smaller than the number of local input/output lines according to the conventional art disclosed in FIG. 36.

Referring to FIG. 31 again, according to an embodiment of the present disclosure, the number of input/output pins that are connected to page buffers included in each of the five stages in each of the first, second, third and fourth page buffer regions R1′, R2′, R3′ and R4′ is two, and two local input/output lines are disposed in each stage. The number of local input/output lines disposed in each stage is two, which is smaller than the number of local input/output lines according to the conventional art disclosed in FIG. 36.

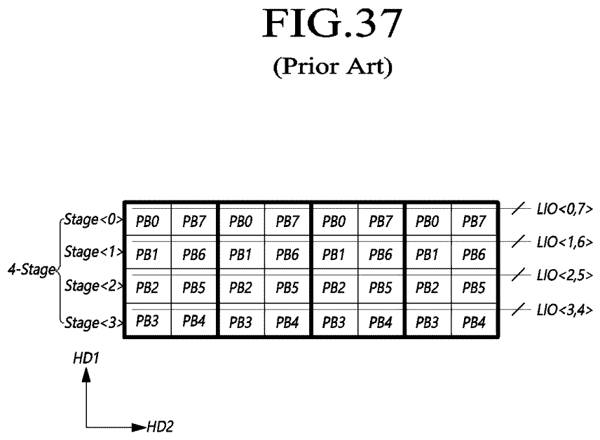

Referring to FIG. 37, page buffers PB of a page buffer circuit are disposed in four stages in the first direction HD1, and input/output pins IO<0:7> are allocated sequentially to the page buffers PB in the first direction HD1. In this case, the number of input/output pins that are connected to page buffers included in each stage is two, and two local input/output lines are disposed in each stage.

Referring to FIG. 34 again, according to an embodiment of the present disclosure, the number of input/output pins that are connected to page buffers included in each of the four stages in each of the first, second, third and fourth page buffer regions R1′, R2′, R3′ and R4′ is one, and one local input/output line is disposed in each stage. The number of local input/output lines disposed in each stage is one, which is smaller than that according to the conventional art disclosed in FIG. 37.

According to embodiments of the present disclosure, because the number of local input/output lines disposed in parallel to each other in each stage is smaller than the number of local input/output lines according to the conventional art, the spacing between neighboring local input/output lines may be increased, and the coupling between neighboring local input/output lines may be reduced.

In addition, because the number of local input/output lines disposed in parallel to each other in each stage is smaller than that according to the conventional art, the number of data output transistors of a page buffer may be reduced, and the area of the page buffer may be reduced.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A memory device comprising:
a plurality of input/output pins; and
a page buffer circuit including a plurality of page buffers that are disposed in a plurality of stages in a first direction, each of the plurality of page buffers is connected to one of the plurality of input/output pins,
wherein the plurality of input/output pins include input/output pins of a first group and input/output pins of a second group, and
wherein page buffers connected to the input/output pins of the first group and page buffers connected to the input/output pins of the second group are divided into a first page buffer region corresponding to the first group and a second page buffer region corresponding to the second group, respectively.

2. The memory device according to claim 1, wherein the first page buffer region and the second page buffer region are arranged in a second direction perpendicular to the first direction.

3. The memory device according to claim 1, further comprising:
a column decoder circuit including a plurality of column decoders; and
local input/output lines connecting the page buffer circuit and the plurality of column decoders,
wherein the local input/output lines comprise:
local input/output lines of a first group connected to page buffers of the first page buffer region; and
local input/output lines of a second group connected to page buffers of the second page buffer region.

4. The memory device according to claim 3, wherein
the local input/output lines of the first group are disposed in the first page buffer region, and
the local input/output lines of the second group are disposed in the second page buffer region.

5. The memory device according to claim 3, wherein
the number of the plurality of input/output pins is eight,
the number of the plurality of stages is six, and
two local input/output lines are disposed in each stage in each of the first and second page buffer regions.

6. The memory device according to claim 3, wherein
the number of the plurality of input/output pins is eight,
the number of the plurality of stages is five, and
four local input/output lines are disposed in each stage in each of the first and second page buffer regions.

7. The memory device according to claim 3, wherein
the number of the plurality of input/output pins is eight,
the number of the plurality of stages is four, and
two local input/output lines are disposed in each stage in each of the first and second page buffer regions.

8. The memory device according to claim 3, wherein
each of the plurality of page buffers includes a data output transistor,
an N (N is an integer) number of local input/output lines are disposed in each of the plurality of stages, and
each of the plurality of page buffers includes an N number of data output transistors.

9. The memory device according to claim 1, further comprising:
a plurality of column decoder regions; and
a plurality of contact open regions,
wherein one of a plurality of odd-numbered stages and one of a plurality of even-numbered stages from among the plurality of stages are disposed between two adjacent column decoder regions among the plurality of column decoder regions, and
wherein one of the plurality of contact open regions is disposed between an odd-numbered stage and an even-numbered stage from among the plurality of stages.

10. The memory device according to claim 1, further comprising:
a plurality of column decoder regions; and
a plurality of contact open regions,
wherein one of a plurality of odd-numbered stages and one of a plurality of even-numbered stages from among the plurality of stages are disposed between two adjacent contact open regions among the plurality of contact open regions, and
wherein one of the plurality of column decoder regions is disposed between the odd-numbered stage and the even-numbered stage.

11. The memory device according to claim 1, wherein
the plurality of page buffers are connected to a plurality of bit lines through bit line contacts, respectively, and
bit lines belonging to one bit line input/output unit are disposed consecutively to neighbor each other.

12. The memory device according to claim 1, wherein
the plurality of page buffers are connected to a plurality of bit lines through bit line contacts, respectively, and
bit line contacts in a single stage of the page buffer circuit are disposed not to be directly adjacent each other.

13. A memory device comprising:
a plurality of input/output pins; and
a page buffer circuit including a plurality of page buffers that are disposed in a plurality of stages in a first direction, each of the plurality of page buffers is connected to one of the plurality of input/output pins,
wherein the plurality of input/output pins include input/output pins of a first group, input/output pins of a second group, input/output pins of a third group and input/output pins of a fourth group, and
wherein page buffers connected to the input/output pins of the first group, page buffers connected to the input/output pins of the second group, page buffers connected to the input/output pins of the third group and page buffers connected to the input/output pins of the fourth group are separated and are arranged into a first page buffer region, a second page buffer region, a third page buffer region and a fourth page buffer region, respectively.

14. The memory device according to claim 13, wherein the first page buffer region, the second page buffer region, the third page buffer region and the fourth page buffer region are arranged in a second direction perpendicular to the first direction.

15. The memory device according to claim 13, further comprising:
a column decoder circuit including a plurality of column decoders; and
local input/output lines connecting the page buffer circuit and the plurality of column decoders,
wherein the local input/output lines comprise:
local input/output lines of a first group connected to page buffers of the first page buffer region;
local input/output lines of a second group connected to page buffers of the second page buffer region;
local input/output lines of a third group connected to page buffers of the third page buffer region; and
local input/output lines of a fourth group connected to page buffers of the fourth page buffer region.

16. The memory device according to claim 15, wherein
the local input/output lines of the first group are disposed in the first page buffer region,
the local input/output lines of the second group are disposed in the second page buffer region,
the local input/output lines of the third group are disposed in the third page buffer region, and
the local input/output lines of the fourth group are disposed in the fourth page buffer region.

17. The memory device according to claim 15, wherein
the number of the plurality of input/output pins is eight,
the number of the plurality of stages is six, and
one local input/output line is disposed in each stage in each of the first, second, third and fourth page buffer regions.

18. The memory device according to claim 15, wherein
the number of the plurality of input/output pins is eight,
the number of the plurality of stages is five, and
two local input/output line are disposed in each stage in each of the first, second, third and fourth page buffer regions.

19. The memory device according to claim 15, wherein
the number of the plurality of input/output pins is eight,
the number of the plurality of stages is four, and
one local input/output line is disposed in each stage in each of the first, second, third and fourth page buffer regions.
